(19) United States
(12) Patent Application Publication
(10) Pub. No.: US 2023/0119495 A1
(43) Pub. Date: Apr. 20, 2023

(54) LIGHT EMITTING DEVICE, DISPLAY DEVICE, PHOTOELECTRIC CONVERSION DEVICE, ELECTRONIC APPARATUS, ILLUMINATION DEVICE, AND MOVING BODY

(71) Applicant: CANON KABUSHIKI KAISHA, Tokyo (JP)

(72) Inventors: Tasuku Kaneda, Kanagawa (JP); Yuki Sato, Tokyo (JP)

(21) Appl. No.: 17/933,555

(22) Filed: Sep. 20, 2022

(30) Foreign Application Priority Data
Oct. 5, 2021 (JP) 2021-164292
Dec. 6, 2021 (JP) 2021-197871
Jul. 25, 2022 (JP) 2022-118156

(51) Int. Cl. H01L 51/52; H01L 27/32

(52) U.S. Cl. CPC H01L 51/524; H01L 51/5284; H01L 27/3276; H01L 27/322

(57) ABSTRACT

A light emitting device in which light emitting elements sealed by a sealing layer are arranged on a surface of a substrate, is provided. Each of the light emitting elements comprises a first electrode arranged between the substrate and the sealing layer, a second electrode arranged between the first electrode and the sealing layer, and an organic light emitting layer arranged between the first electrode and the second electrode. The light emitting device further comprises an insulating layer configured to cover a edge portion of the first electrode and arranged between the substrate and the sealing layer in a portion between two adjacent light emitting elements, and a light shielding member arranged between the two adjacent light emitting elements, extending through the insulating layer, and extending in the insulating layer and the sealing layer in a direction intersecting the surface.

### BACKGROUND OF THE INVENTION

### Field of the Invention

The present invention relates to a light emitting device, a display device, a photoelectric conversion device, an electronic apparatus, an illumination device, and a moving body.

### Description of the Related Art

Interest in a light emitting device using a self-light emitting element such as an organic electroluminescence (EL) element has increased. There is a problem that as the luminance and resolution of a light emitting element increase, the color reproducibility deteriorates due to leakage of light to an adjacent pixel. Japanese Patent Laid-Open No. 2019-102462 discloses an electroluminescent display device that suppresses color mixing by arranging, in a portion corresponding to part of a sealing film between pixels, a partition wall using a material of a refractive index lower than that of the sealing film.

### SUMMARY OF THE INVENTION

A technique of preventing the color reproducibility from deteriorating along with a further increase in resolution of a light emitting device is required.

Some embodiments of the present invention provide a technique advantageous in increasing the resolution of a light emitting device and improving the color reproducibility.

According to some embodiments, a light emitting device in which a plurality of light emitting elements sealed by a sealing layer are arranged on a main surface of a substrate, wherein each of the plurality of light emitting elements comprises a first electrode arranged between the substrate and the sealing layer, a second electrode arranged between the first electrode and the sealing layer, and an organic layer including a light emitting layer arranged between the first electrode and the second electrode, and the light emitting device further comprises an insulating layer configured to cover a peripheral edge portion of the first electrode and arranged between the substrate and the sealing layer in a portion between two adjacent light emitting elements among the plurality of light emitting elements, and a light shielding member arranged between the two adjacent light emitting elements among the plurality of light emitting elements, extending through the insulating layer, and extending in the insulating layer and the sealing layer in a direction intersecting the main surface, is provided.

Further features of the present invention will become apparent from the following description of exemplary embodiments (with reference to the attached drawings).

### BRIEF DESCRIPTION OF THE DRAWINGS

FIG. 1 is a plan view showing an example of the arrangement of a light emitting device according to an embodiment;

FIG. 2 is a sectional view showing an example of the arrangement of the light emitting device shown in FIG. 1;

FIG. 3 is a sectional view showing an example of the arrangement of the light emitting device shown in FIG. 1;

FIGS. 4A and 4B are sectional views showing a method of manufacturing the light emitting device shown in FIG. 1;

FIGS. 5A and 5B are sectional views showing the method of manufacturing the light emitting device shown in FIG. 1;

FIGS. 6A and 6B are sectional views showing the method of manufacturing the light emitting device shown in FIG. 1;

FIGS. 7A and 7B are sectional views showing the method of manufacturing the light emitting device shown in FIG. 1;

FIG. 8 is a sectional view showing an example of the arrangement of the light emitting device shown in FIG. 1;

FIG. 9 is a sectional view showing an example of the arrangement of the light emitting device shown in FIG. 1;

FIG. 10 is a plan view showing a modification of the light emitting device shown in FIG. 1;

FIG. 11 is a sectional view showing an example of the arrangement of the light emitting device shown in FIG. 10;

FIG. 12 is a sectional view showing a modification of the light emitting device shown in FIG. 11;

FIGS. 13A to 13C are views showing an example of an image forming device using the light emitting device according to the embodiment;

FIG. 14 is a view showing an example of a display device using the light emitting device according to the embodiment;

FIG. 15 is a view showing an example of a photoelectric conversion device using the light emitting device according to the embodiment;

FIG. 16 is a view showing an example of an electronic apparatus using the light emitting device according to the embodiment;

FIGS. 17A and 17B are views each showing an example of a display device using the light emitting device according to the embodiment;

FIG. 18 is a view showing an example of an illumination device using the light emitting device according to the embodiment;

FIG. 19 is a view showing an example of a moving body using the light emitting device according to the embodiment; and

FIGS. 20A and 20B are views each showing an example of a wearable device using the light emitting device according to the embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

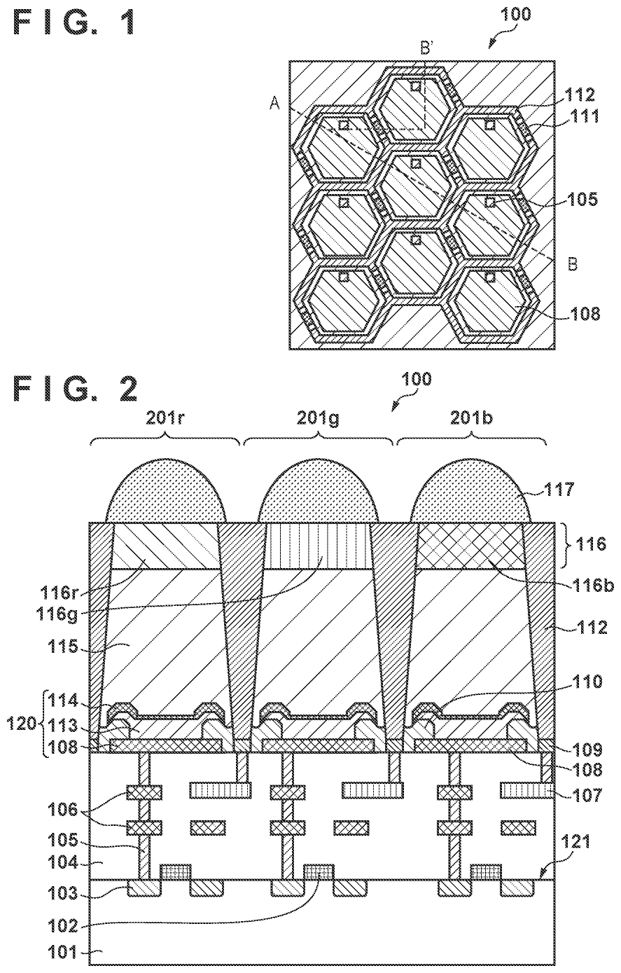

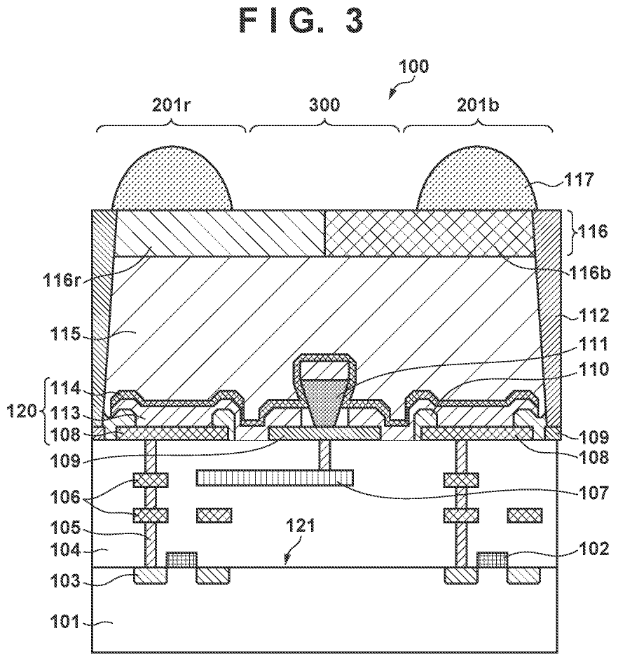

A photoelectric conversion device according an embodiment of the present disclosure will be described with reference to FIGS. 1 to 12. FIG. 1 is a plan view showing an example of the arrangement of a light emitting device 100 according to the embodiment. FIG. 2 is a sectional view taken along a line A-B shown in FIG. 1. FIG. 3 is a sectional view taken along a line A-B′ shown in FIG. 1.

In the light emitting device 100, a plurality of light emitting elements 120 sealed by a sealing layer 115 are arranged on a main surface 121 of a substrate 101. Each of the plurality of light emitting elements 120 includes an electrode 108 arranged between the substrate 101 and the sealing layer 115, an electrode 114 arranged between the electrode 108 and the sealing layer 115, and an organic layer 113 including a light emitting layer arranged between the electrodes 108 and 114. As shown in FIGS. 1 to 3, the electrode 108 is individual for each light emitting element 120, and can be called a lower electrode, an individual electrode, or the like. The electrode 108 functions as an anode electrode in this embodiment but may function as a cathode electrode. The electrode 114 can be called an upper electrode or the like. The electrode 114 functions as a cathode electrode in this embodiment but may function as an anode electrode.

As shown in FIG. 1, in this embodiment, the electrode 108 of the light emitting element 120 is formed in a hexagonal shape but may be formed in a rectangular shape or another polygonal shape. A plug 105 is a conductive pattern to be electrically connected to a wiring pattern 106, and is electrically connected to the electrode 108.

The electrode 108 is electrically separated from a power supply plug 111 and a light shielding member 112 (to be described in detail later). As shown in FIG. 1, the power supply plug 111 can be provided in a gap of the light shielding member 112. The power supply plug 111 supplies power to the electrode 114. The power supply plug 111 and the light shielding member 112 surround each of the plurality of light emitting elements 120 in cooperation with each other. However, as shown in FIG. 1, a space is provided between the power supply plug 111 and the light shielding member 112, and thus the power supply plug 111 and the light shielding member 112 do not completely surround each light emitting element 120. It can also be said that the light shielding member 112 is arranged to partially surround each of the plurality of light emitting elements 120.

FIG. 1 shows an example in which one power supply plug 111 and the light shielding member 112 are provided for one electrode 108 but the present invention is not limited to this. For example, for one electrode 108, a plurality of power supply plugs 111 and the light shielding member 112 may be formed in a slit shape, and the densities and areas of the power supply plug 111 and the light shielding member 112 may be changed arbitrarily.

As shown in FIG. 2, pixels 201 each including the light emitting element 120 are arranged on the main surface 121 of the substrate 101. On the substrate 101, a gate insulating film and a gate electrode 102 forming a transistor for driving each light emitting element 120, a source/drain region 103, and an element isolation region (not shown) having, for example, an STI structure are arranged.

On the elements such as the transistors arranged on the substrate 101, an interlayer insulating layer 104 is arranged. In the interlayer insulating layer 104, a wiring layer including the wiring pattern 106 is arranged. In the arrangement shown in FIGS. 2 and 3, two wiring layers each including the wiring pattern 106 are arranged. However, one wiring layer or three or more wiring layers may be arranged. The gate electrode 102, the source/drain region 103, and the wiring pattern 106 are electrically connected via the plug 105. The interlayer insulating layer 104 can be formed by depositing BPSG (Boro-Phospho Silicate Glass) using a thermal CVD (Chemical Vapor Deposition) method, silicon oxide (SiO) using a plasma CVD method, or the like. The wiring pattern 106 may be an aluminum (Al)-based wiring or a copper (Cu)-based wiring, and the Al-based wiring and the Cu-based wiring may be mixed over the plurality of wiring layers. The plug 105 can be formed by, for example, a stacked structure of tungsten (W) and a barrier metal such as titanium (Ti)/titanium nitride (TiN). In the interlayer insulating layer 104, a power supply wiring pattern 107 for supplying power to the electrode 114 can be arranged. The power supply wiring pattern 107 may be arranged in the same wiring layer as that of the wiring pattern 106 or in a wiring layer different from that of the wiring pattern 106. An arbitrary potential is supplied to the power supply wiring pattern 107.

On the interlayer insulating layer 104, the electrodes 108 and a conductive pattern 109 are arranged. The conductive pattern 109 and the electrode 108 are electrically separated from each other but can be arranged in the same layer. The constituent elements (for example, the conductive pattern 109 and the electrodes 108) arranged in the same layer indicate those obtained by forming a conductive layer such as a metal layer and patterning the one formed conductive layer.

An insulating layer 110 is arranged to cover the peripheral edge portion of the electrode 108 between the substrate 101 and the sealing layer 115 in a portion between two adjacent light emitting elements 120 among the plurality of light emitting elements 120. The insulating layer 110 can be arranged between the interlayer insulating layer 104 and the sealing layer 115. For the insulating layer 110, for example, a material such as silicon oxide can be used. As shown in FIGS. 2 and 3, the insulating layer 110 has a role of covering the peripheral edge portion of the electrode 108 and defining a light emitting region. The insulating layer 110 suppresses a leakage current between the two adjacent light emitting elements 120. The insulating layer 110 is also called a bank or a pixel separation film.

The light shielding member 112 is arranged on the conductive pattern 109. The light shielding member 112 is arranged between the two adjacent light emitting elements among the plurality of light emitting elements 120, and extends through the insulating layer 110. Furthermore, as shown in FIGS. 2 and 3, the light shielding member 112 may extend through the sealing layer 115. A state in which the first member “extends through” the second member indicates a state in which, in a given section shown in FIG. 2, the first member communicates from one end of the second member to the other end and is in contact with the communication port formed in the second member. If there is another member between the first member and the second member, the other member and the first member need only be in contact with each other. The light shielding member 112 may be supplied with an arbitrary potential via the power supply wiring pattern 107 or may be floated.

In this embodiment, the electrode 108 and the conductive pattern 109 have a stacked structure of AlCu (Al added with Cu of 0.5 (atm %)) and a barrier metal such as Ti/TiN. The light shielding member 112 has a stacked structure of tungsten and a barrier metal such as Ti/TiN. However, the materials of the electrode 108, the conductive pattern 109, and the light shielding member 112 are not limited to them. For example, the light shielding member 112 may be made of an alloy containing Al with a high reflectance, or an insulator with a low refractive index.

Although a manufacturing method will be described in detail later, the light shielding member 112 has an inverted tapered shape in which a sectional area in a direction parallel to the main surface 121 of the substrate 101 is larger as the distance from the substrate 101 becomes longer. When the light shielding member 112 has the inverted tapered shape, step disconnection of the organic layer 113 occurs, thereby making it possible to suppress stray light generated when light emitted from the light emitting element 120 enters the adjacent pixel 201 or a leakage current between the light emitting elements 120 via the organic layer 113. A taper angle between the side wall of the light shielding member 112 and a virtual plane parallel to the main surface 121 of the substrate 101 can arbitrarily be set in accordance with the wrapping characteristic of deposition of the organic layer 113. As shown in FIGS. 2 and 3, the light shielding member 112 includes a portion extending through the sealing layer 115. In a direction parallel to a virtual line connecting the centers of the electrodes 108 of the two adjacent light emitting elements 120 among the plurality of light emitting elements 120, the width of the portion extending through the sealing layer 115 at a position where the height of the portion is halved can be set to, for example, 5 μm or less. The width at a height where the portion, extending through the sealing layer 115, of the light shielding member 112 is halved can be set to 2 μm or less. This can reduce the area of a region between the pixels 201 (light emitting elements 120), which does not contribute to light emission, thereby suppressing an adverse effect on reduction of a pixel pitch.

The organic layer 113 including the light emitting layer and the above-described insulating layer 110 are arranged on the electrode 108. The organic layer 113 includes at least the light emitting layer containing an organic light emitting material, and may include, as additional function layers, for example, a charge transport layer, a charge blocking layer, and a carrier generation layer.

The electrode 114 is arranged on the organic layer 113. The electrode 114 may be formed by a thin film of a transparent material to cause light generated in the organic layer 113 to exit to the upper surface without blocking the light. In this embodiment, the electrode 114 is formed by a thin film of gold, platinum, silver, aluminum, chromium, magnesium, or an alloy thereof.

In the arrangement shown in FIG. 2, the light shielding member 112 is not in contact with the electrode 114. In this case, as described above, power may be supplied to the electrode 114 using the power supply plug 111. In this case, the light shielding member 112 and the electrode 114 may be electrically connected to each other, and a potential supplied to the power supply plug 111 can be applied from the power supply wiring pattern 107 to the light shielding member 112. The structure of the power supply plug 111 will be described with reference to FIG. 3.

As shown in FIG. 3, a contact region 300 is arranged between pixels 201r and 201b. In the contact region 300, the conductive pattern 109 and the power supply plug 111 that are electrically separated from the electrode 108 are formed. The conductive pattern 109 is connected to the power supply wiring pattern 107 via the plug 105. The power supply plug 111 has the stacked structure of tungsten and a barrier metal such as Ti/TiN in this embodiment but may have another appropriate structure. The power supply plug 111 is formed in an inverted tapered shape. When the power supply plug 111 has an inverted tapered shape, step disconnection of the organic layer 113 occurs. The electrode 114 and the power supply plug 111 can electrically be connected using a portion where the organic layer 113 is not deposited.

With the above structure, the potential of the electrode 114 provided in each light emitting element 120 is supplied from the power supply wiring pattern 107 via the power supply plug 111. The power supply wiring pattern 107 may be a wiring pattern thicker than the power supply plug 111. The light emitting device 100 including a large-area display region (a region where the light emitting element 120 (pixel 201) is arranged) can reduce the influence of the wire resistance of routing by the power supply wiring pattern 107. By electrically connecting the power supply wiring pattern 107 and the power supply plug 111 to each other, the potential of the electrode 114 in each light emitting element 120 can be made uniform, and luminance unevenness in the display region of the light emitting device 100 can be reduced, thereby obtaining satisfactory image quality.

The sealing layer 115 is arranged on the electrode 114. The sealing layer 115 may be a composite film made of silicon nitride (SiN) deposited using the plasma CVD method, aluminum oxide (Al₂O₃) deposited using the ALD (Atomic Layer Deposition) method, and the like to prevent permeation of water into the substrate 101, the organic layer 113, and the electrode 114.

On the sealing layer 115, in other words, at a position farther from the substrate 101 than the sealing layer 115, a color filter layer 116 may be arranged. Furthermore, another layer such as a planarizing layer may be arranged between the sealing layer 115 and the color filter layer 116.

In this embodiment, the light emitting element 120 emits white light, and a color filter layer 116r that transmits red light and absorbs green light and blue light is arranged in the pixel 201r. A color filter layer 116g that transmits green light and absorbs red light and blue light is arranged in a pixel 201g. Furthermore, a color filter layer 116b that transmits blue light and absorbs red light and green light is arranged in the pixel 201b. However, the present invention is not limited to this, and a combination of the emission color of the light emitting element and the transmission color of the color filter layer 116 is appropriately selected. If the light emitting device 100 displays only the emission color of the light emitting element 120 or a plurality of kinds of light emitting elements 120 whose emission colors are different from each other are arranged, the color filter layer 116 need not be arranged.

A microlens 117 may be arranged on the color filter layer 116. If the color filter layer 116 is not arranged, as described above, a microlens may be arranged on the sealing layer 115. That is, the light emitting device 100 may include the microlens 117 at a position farther from the substrate 101 than the sealing layer 115. Another layer such as a planarizing layer may be arranged between the microlens 117 and the color filter layer 116 or the sealing layer 115. The microlens 117 may be formed in a uniform shape over the entire display region of the light emitting device 100 where the light emitting element 120 is arranged or the microlens 117 having a partially different radius of curvature may be formed.

With the above structure, the substrate 101 transmits an electrical signal to the electrodes 108 and 114, and light emitted in the organic layer 113 exits. In this embodiment, the light shielding member 112 extends through the insulating layer 110 and the sealing layer 115 and is also arranged to the color filter layer 116. Furthermore, the light shielding member 112 extends through the color filter layer 116 to be in contact with the microlens 117. This structure separates the pixels 201r, 201g, and 201b. This can suppress guided light in the films of the insulating layer 110, the organic layer 113, the electrode 114, the sealing layer 115, and the color filter layer 116 between the pixels 201 from leaking to the adjacent pixel 201. That is, it is possible to improve the color reproducibility of the light emitting device 100. As described above, the width of the light shielding member 112 arranged between the pixels 201 can be thinned to 2 μm or less. This can cope with an increase in resolution of the display region of the light emitting device 100. In addition, the light emitting device 100 according to this embodiment can reduce luminance unevenness while suppressing color mixing between the pixels 201 by using the light shielding member 112 and the power supply plug 111.

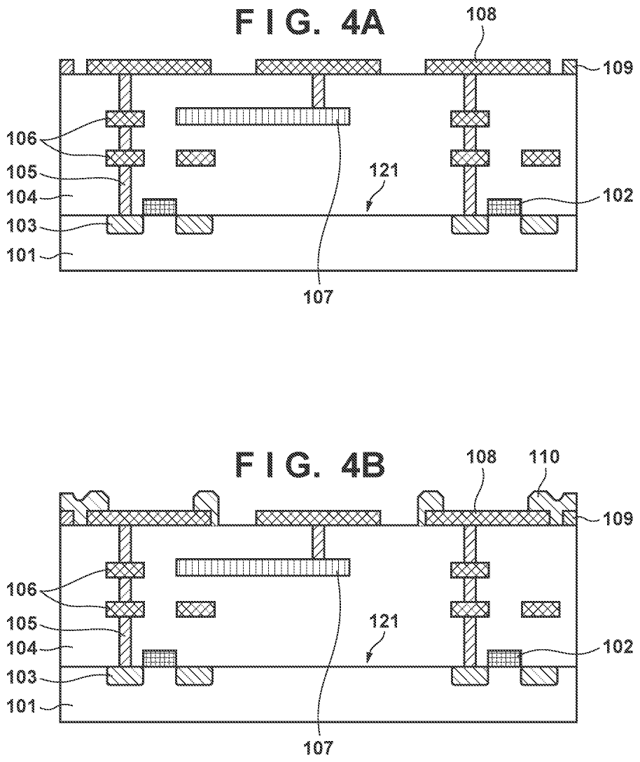

A method of manufacturing the light emitting device 100 will be described next with reference to FIGS. 4A and 4B to 7A and 7B. As shown in FIG. 4A, the interlayer insulating layer 104 including the wiring patterns 106 and the elements such as transistors is formed on the main surface 121 of the substrate 101. For example, a barrier metal such as Ti/TiN and AlCu are deposited by a sputtering method, and the wiring patterns 106 and the power supply wiring pattern 107 are formed by performing a photolithography process and a dry etching process. After that, silicon oxide is deposited on the wiring patterns 106 and the power supply wiring pattern 107 using the plasma CVD method, and the upper surface of the interlayer insulating layer 104 is planarized using the CMP (Chemical Mechanical Polishing) method. After the upper surface of the interlayer insulating layer 104 is planarized, a hole is formed in the interlayer insulating layer 104 by performing a photolithography process and a dry etching process. Next, tungsten is embedded in the hole formed in the interlayer insulating layer 104 using the CVD method, and tungsten remaining on the upper surface of the interlayer insulating layer 104 is polished using the CMP method, thereby forming the plug 105. After the formation of the plug 105, AlCu is deposited on the interlayer insulating layer 104 by the sputtering method, and the electrode 108 and the conductive pattern 109 are formed by performing a photolithography process and a dry etching process.

Next, as shown in FIG. 4B, an insulating film made of silicon oxide or silicon nitride is deposited using the plasma CVD method, and then the insulating layer 110 is formed by performing a photolithography process and a dry etching process. The insulating layer 110 can be formed in a two-stage tapered shape on the electrode 108 by switching a dry etching condition a plurality of times.

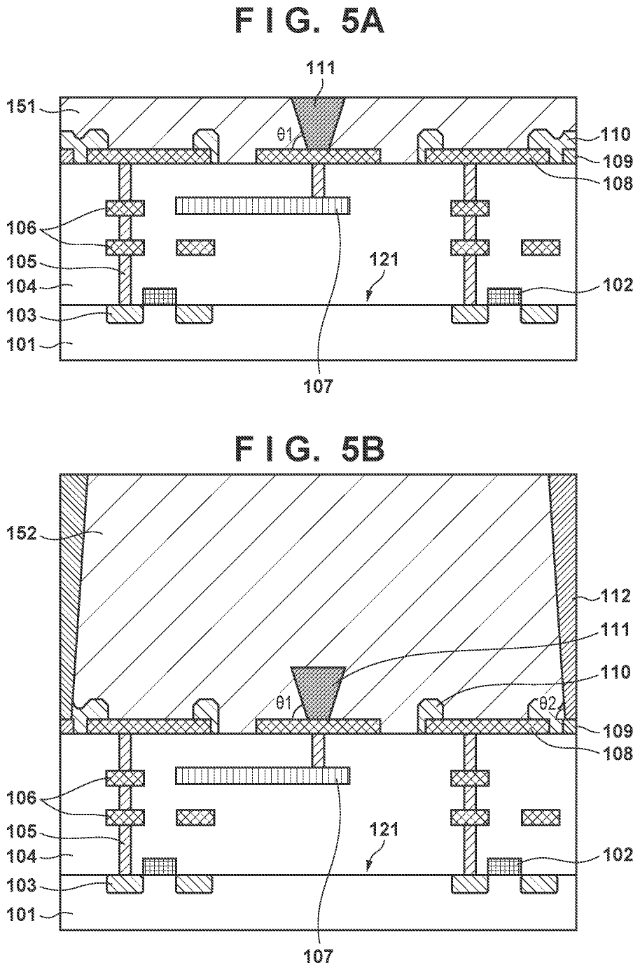

After the formation of the insulating layer 110, an insulating film 151 made of silicon oxide or the like is deposited using the plasma CVD method, and the upper surface of the insulating film 151 is planarized using the CMP method, as shown in FIG. 5A. Next, a hole having an inverted tapered shape with a taper angle θ1 is formed in the insulating film 151 by performing a photolithography process and a dry etching process. As shown in FIG. 5A, the taper angle is an angle between the side wall of the hole formed in the insulating film 151 and a virtual plane parallel to the main surface 121 of the substrate 101. The taper angle of the hole having the inverted tapered shape can be controlled by changing the deposition gas ratio, power ratio, and process temperature at the time of etching. Tungsten is embedded in the hole formed in the insulating film 151 using the CVD method, and tungsten remaining on the upper surface of the insulating film 151 is polished using the CMP method, thereby forming the power supply plug 111.

A method of forming the power supply plug 111 is not limited to the above-described method. For example, in the process shown in FIG. 5A, after silicon oxide is thinly deposited using the plasma CVD method, the silicon oxide on the conductive pattern 109 is removed using a photolithography process and a dry etching process, and tungsten is deposited. By etching tungsten and silicon oxide by performing a photolithography process and a dry etching process, a W film having an inverted tapered shape can remain only on the upper portion of the conductive pattern 109. In this case, the height of the power supply plug 111 is decided by a film thickness with which tungsten is deposited, thereby making it easy to control the plug height.

After the formation of the power supply plug 111, an insulating film 152 made of silicon oxide or the like is deposited on the power supply plug 111 using the plasma CVD method, and the upper surface of the insulating film 152 is planarized using the CMP method, as shown in FIG. 5B. Next, a hole having an inverted tapered shape with a taper angle θ2 is formed in the insulating film 152 by performing a photolithography process and a dry etching process. As shown in FIG. 5B, the taper angle is an angle between the side wall of the hole formed in the insulating film 152 and a virtual plane parallel to the main surface 121 of the substrate 101. The taper angle of the hole having the inverted tapered shape can be controlled by changing the deposition gas ratio, power ratio, and process temperature at the time of etching. Tungsten is embedded in the hole formed in the insulating film 152 using the CVD method, and tungsten remaining on the upper surface of the insulating film 152 is polished using the CMP method, thereby forming the light shielding member 112.

At this time, the taper angle θ2 between the side wall of the light shielding member 112 and the virtual plane parallel to the main surface 121 of the substrate 101 may be 40° or larger. This is to prevent the light shielding member 112 from blocking light emitted in the light emitting layer of the organic layer 113. In other words, the above-described taper angle is required to suppress a decrease in opening ratio of the light emitting element 120 and prevent deterioration of the emission efficiency of the pixel 201. Note that the light shielding member 112 is shown to have an inverted tapered shape in which a sectional area in the direction parallel to the main surface 121 continuously increases as the distance from the main surface 121 of the substrate 101 becomes longer. However, the present invention is not limited to this, and the light shielding member 112 may have a shape in which the sectional area increases stepwise.

The relationship between the taper angle θ1 of the power supply plug 111 and the taper angle 02 of the light shielding member 112 may be given by θ1<θ2. This can cause step disconnection of the organic layer 113 in the power supply plug 111, thereby making the electrode 114 and the power supply plug 111 surely contact each other.

In this embodiment, the light shielding member 112 extends to separate from the substrate 101 from the height at which the electrode 108 is arranged. This is because the light shielding member 112 is arranged on the conductive pattern 109 formed in the same layer as that of the electrode 108. However, the present invention is not limited to this. For example, the conductive pattern 109 need not be arranged, and the light shielding member 112 may be arranged from the power supply wiring pattern 107 or the like in the interlayer insulating layer 104. Furthermore, the light shielding member 112 may extend through the interlayer insulating layer 104 to be in contact with the main surface 121 of the substrate 101.

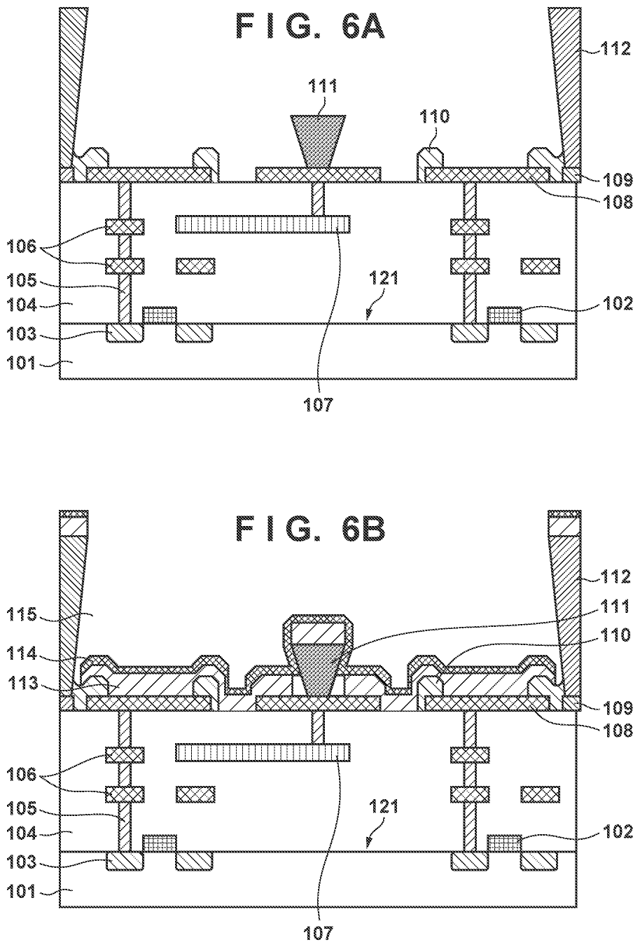

Next, as shown in FIG. 6A, the insulating film 152 is removed by performing an anisotropic dry etching process and an isotropic etching process. To reliably connect the power supply plug 111 and the electrode 114 to each other, it is necessary to remove the insulating film 152 on the side wall of the power supply plug 111. As shown in FIG. 1, since the light shielding member 112 is formed to surround each light emitting element 120 and to be shared by the plurality of light emitting elements 120, even a structure having a high aspect ratio falls down during manufacturing with a low probability. With this manufacturing method, the light shielding member 112 can be made such a thin member that the width in the direction parallel to the virtual line connecting the centers of the electrodes 108 of the two adjacent light emitting elements among the plurality of light emitting elements 120 is 2 μm or less. This width is a width at a position where the height of the portion, extending through the sealing layer 115, of the light shielding member 112 is halved, as described above.

After the insulating film 152 is etched, the organic layer 113 is formed by a vacuum deposition method using a vapor deposition mask with a desired opening pattern, as shown in FIG. 6B. The vapor deposition mask may be a mask in which the entire light emitting region is opened or a vapor deposition mask in which only a portion inside the electrode 108 is opened for each pixel 201. The organic layer 113 is formed using deposition, and a portion where no organic layer 113 is deposited exists in a portion as the shadow of the inverted tapered shape of each of the power supply plug 111 and the light shielding member 112. After the formation of the organic layer 113, the electrode 114 is formed using the sputtering method. The electrode 114 is a thin film of a transparent material, and a thin film of gold, platinum, silver, aluminum, chromium, magnesium, or an alloy thereof is used in this embodiment. When the electrode 114 is formed using a deposition method having excellent coverage performance for unevenness, as compared with the vacuum deposition method, the electrode 114 and the power supply plug 111 can electrically be connected to each other in a step disconnection portion of the organic layer 113. The method of forming the electrode 114 is not limited to the sputtering method, and a deposition method having excellent coverage performance, such as the CVD method, may be used. After the formation of the electrodes 114, the sealing layer 115 having a composite structure of silicon nitride deposited using the plasma CVD method and aluminum oxide deposited using the ALD method is formed. By setting the film thickness of silicon nitride contained in the sealing layer 115 to 2 μm or more, it is possible to prevent permeation of water in the atmosphere, and maintain the life and reliability of the organic layer 113.

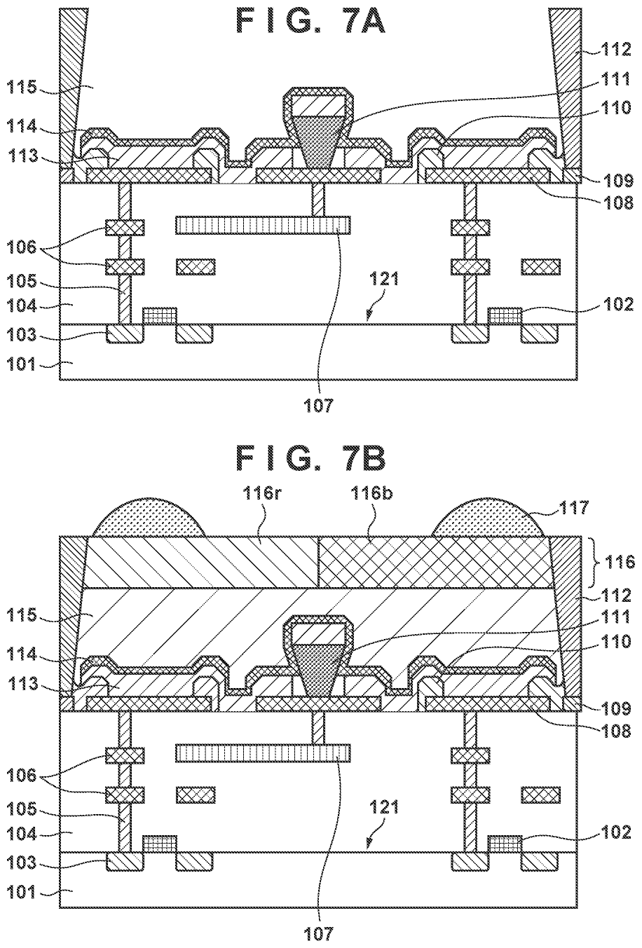

Next, as shown in FIG. 7A, the upper surface of the sealing layer 115 is planarized using the CMP method. The light shielding member 112 can be used to detect the end point of the planarization, and the planarization of the sealing layer 115 can be stopped at the height of the light shielding member 112. The organic layer 113 and the electrode 114 are formed on the light shielding member 112, as shown in FIG. 6B, but can selectively be removed using a dry etching process or a wet etching process. In addition, the planarized sealing layer 115 is etched back to a predetermined depth.

After the sealing layer 115 is etched back, the color filter layer 116 is formed on the sealing layer 115 using the photolithography method, as shown in FIG. 7B. At this time, the heights of the upper surfaces of the color filter layer 116 and the light shielding member 112 may match each other, as shown in FIG. 7B. Alternatively, the heights of the upper surfaces of the color filter layer 116 and the light shielding member 112 need not match each other. For example, the upper surface of the light shielding member 112 may exist in the color filter layer 116. By forming the microlens 117 after the formation of the color filter layer 116, the light emitting device 100 is formed, as shown in FIGS. 2 and 3.

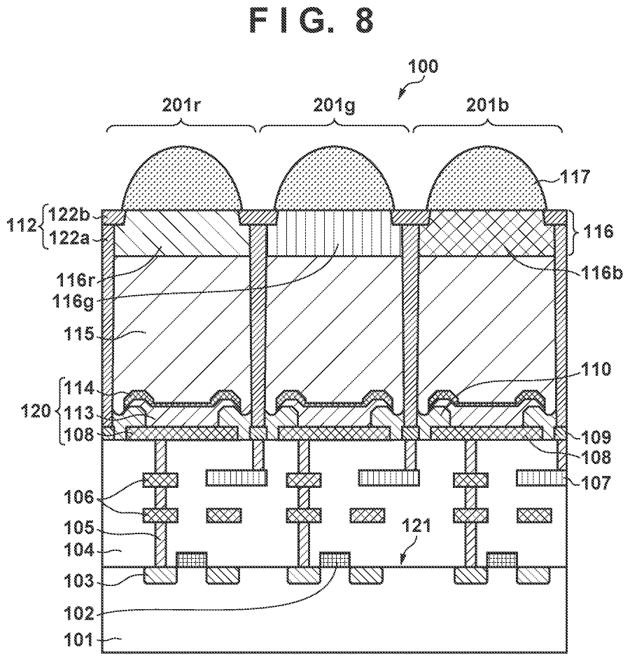

FIG. 8 is a sectional view showing a modification of the sectional view of the light emitting device 100 shown in FIG. 2. FIG. 8 shows a sectional structure taken along the line A-B shown in FIG. 1. In the arrangement shown in FIG. 8, the shape of the light shielding member 112 is different from that in the arrangement shown in FIG. 2. The remaining components may be the same as those described above. Thus, different points will mainly be described and a description of the components that may be the same as those described above will be omitted appropriately.

In the arrangement shown in FIG. 8, the light shielding member 112 includes a portion 122a and a portion 122b larger, in a width in the direction parallel to the virtual line connecting the centers of the electrodes 108 of the two adjacent light emitting elements among the plurality of light emitting elements 120, than the portion 122a of the upper end portion. As a result, the upper end portion of the light shielding member 112 has an eaves shape.

The portions 122a and 122b of the light shielding member 112 may have a stacked structure of tungsten and a barrier metal such as Ti/TiN, and may be made of an alloy containing Al with a high reflectance. The portions 122a and 122b may be formed using the same material or different materials.

The eaves shape using the portion 122b can reliably cause step disconnection of the organic layer 113 between the light emitting elements 120. More specifically, when forming the eaves shape of the portion 122b, it is possible to correctly control the width of the eaves by the line width of the mask pattern of the portion 122b. This can improve the controllability of step disconnection between the light emitting elements 120 of the organic layer 113, as compared with the arrangement shown in FIG. 2. By controlling step disconnection of the organic layer 113, it is possible to suppress a leakage current between the light emitting elements 120 via the organic layer 113, and improve the color reproducibility of the light emitting device 100.

As a method of manufacturing the portion 122b of the light shielding member 112, a barrier metal such as Ti/TiN and tungsten are deposited on the upper surfaces of the light shielding member 112 (portion 122a) and the insulating film 152 using the sputtering method and the CVD method after the process shown in FIG. 5B. Next, the portion 122b of the light shielding member 112 is patterned using a photolithography process and a dry etching process. After that, the process of FIG. 6A and the subsequent processes may be same as those described above.

FIG. 9 is a sectional view showing a modification of the sectional view of the light emitting device 100 shown in FIG. 2. FIG. 9 shows a sectional structure taken along the line A-B shown in FIG. 1. In the arrangement shown in FIG. 9, the shape of the light shielding member 112 is different from that in the arrangement shown in FIG. 2. The remaining components may be the same as those described above. Thus, different points will mainly be described and a description of the components that may be the same as those described above will be omitted appropriately.

The light shielding member 112 shown in FIG. 9 includes a portion 132b arranged in the color filter layer 116 and a portion 132a contacting the portion 132b and arranged on a side closer to the substrate 101 than the portion 132b. At this time, the width of the upper end, in contact with the portion 132b, of the portion 132a in the direction parallel to the virtual line connecting the centers of the electrodes 108 of the two adjacent light emitting elements among the plurality of light emitting elements 120 is larger than the width of the portion 132b in the direction.

The portions 132a and 132b of the light shielding member 112 may have, for example, a stacked structure of tungsten and a barrier metal such as Ti/TiN, and may be made of an alloy containing Al with a high reflectance. The portions 132a and 132b may be formed using the same material or different materials.

By decreasing the height of the portion 132a of the light shielding member 112, it is possible to decrease the aspect ratio of the portion 132a, and improve the controllability of the taper angle θ2 when forming the portion 132a. In addition, the aspect ratio of the portion 132b of the light shielding member 112 can be suppressed low, and it is possible to improve the flatness of the upper end portion of the portion 132b. This can improve the flatness of the underlying layer when forming the microlens 117 on the portion 132b of the light shielding member 112. This can stabilize the shape of the microlens 117, and suppress color mixing between the pixels 201 without influencing the light collection efficiency of the microlens 117.

As a method of manufacturing the portion 132b of the light shielding member 112, the height of the upper surface of the sealing layer 115 is made match the light shielding member 112 (portion 132a) in the process shown in FIG. 7A. Next, a barrier metal such as Ti/TiN and tungsten are deposited on the upper surfaces of the light shielding member 112 (portion 132a) and the sealing layer 115 using the sputtering method and the CVD method. After that, the portion 132b of the light shielding member 112 is patterned using a photolithography process and a dry etching process. After that, the process of FIG. 7B and the subsequent processes may be same as those described above.

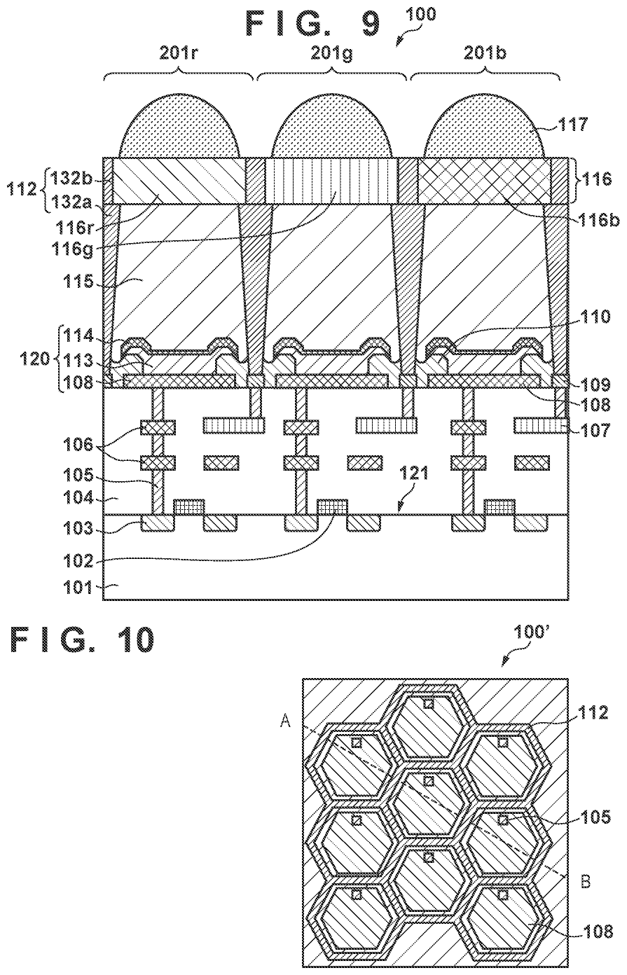

FIG. 10 is a plan view of a light emitting device 100′ as a modification of the light emitting device 100 shown in FIG. 1. As compared with the light emitting device 100 shown in FIG. 1, in the light emitting device 100′ shown in FIG. 10, the light shielding member 112 is arranged to surround each of the plurality of light emitting elements 120. In addition, no power supply plug 111 is arranged.

In the light emitting device 100 shown in FIG. 1, the power supply plug 111 for supplying power to the electrode 114 needs to be provided in a gap of the light shielding member 112. In this structure, since the light shielding member 112 is partially formed, the color mixing suppression effect between the pixels 201 may deteriorate. On the other hand, the light emitting device 100′ shown in FIG. 10 can further improve the color mixing suppression effect, as compared with the light emitting device 100, by continuously arranging the light shielding member 112 to surround the periphery of each light emitting element 120.

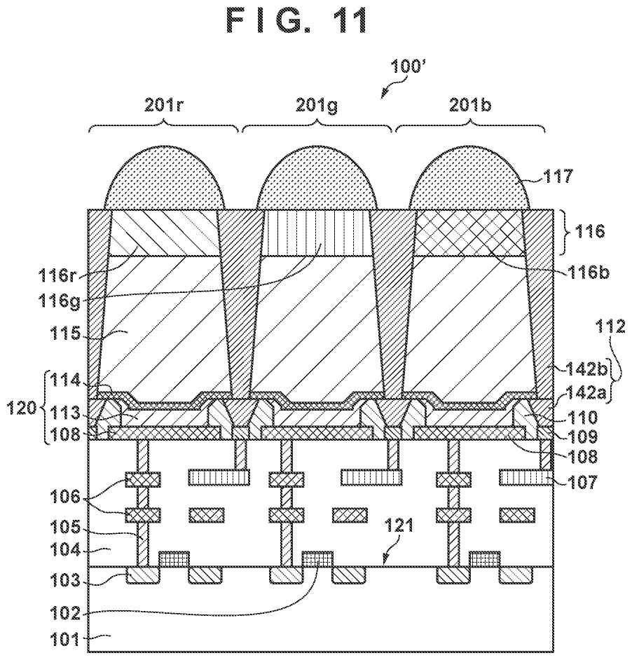

FIG. 11 is a sectional view taken along a line A-B shown in FIG. 10. Points of the light emitting device 100′ different from the light emitting device 100 shown in FIG. 2 will mainly be described and a description of components that may be same as in the light emitting device 100 will be omitted appropriately.

As shown in FIG. 11, in the light emitting device 100′, the light shielding member 112 includes two portions of a portion 142a extending through the insulating layer 110 and a portion 142b extending through the sealing layer 115 and the electrode 114. As shown in FIG. 11, the portion 142b may extend through the color filter layer 116 to be in contact with the microlens 117. Furthermore, the structure of the light shielding member 112 shown in FIG. 8 or 9 described above may be added to the light emitting device 100′.

The portion 142a of the light shielding member 112 has an inverted tapered shape. The portion 142a and the insulating layer 110 suppress the step of the underlying layer when forming the electrode 114, and the electrode 114 and the portion 142a can electrically be connected without causing step disconnection of the electrode 114. That is, the light shielding member 112 is in contact with the electrode 114. As a result, it is possible to supply power from the power supply wiring pattern 107 to the electrode 114 via the light shielding member 112. With the above arrangement, the adjacent pixels 201 are separated more completely using the light shielding member 112 to improve the color reproducibility, and the potential of the electrode 114 is stabilized using the portion 142a, thereby reducing luminance unevenness.

As a method of manufacturing the light emitting device 100′ shown in FIGS. 10 and 11, the portion 142a of the light shielding member 112 is formed by the same process as the process of forming the power supply plug 111 in the process shown in FIG. 5A without forming the insulating layer 110 in the process shown in FIG. 4B. Next, an insulating film made of silicon oxide or silicon nitride is deposited using the plasma CVD method or the like, the insulating film on the electrode 108 is etched back so as to remain on the side wall of the portion 142a, thereby forming the insulating layer 110. The insulating layer 110 can be formed on the side wall of the portion 142a to have a two-stage tapered shape by switching a dry etching condition a plurality of times. The material of the insulating layer 110 may be any material that can ensure selectivity in the dry etching process after the formation of the insulating layer 110. The process of FIG. 5B and the subsequent processes may be the same as those described above.

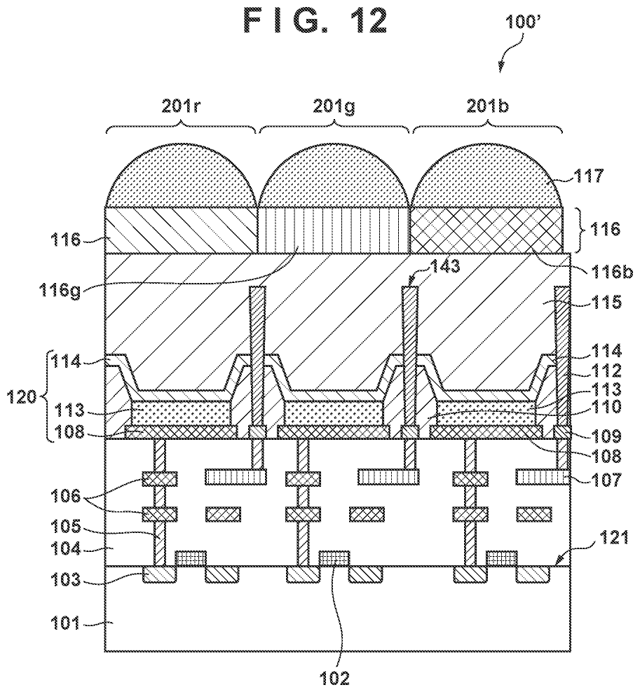

FIG. 12 is a sectional view showing a modification of the sectional view of the light emitting device 100′ shown in FIG. 11. In each of the above-described embodiments, the light shielding member 112 extends through the insulating layer 110 and the sealing layer 115. The present invention, however, is not limited to this. As shown in FIG. 12, the light shielding member 112 extends through the insulating layer 110, and extends in the insulating layer 110 and the sealing layer 115 in a direction intersecting the main surface 121 of the substrate 101. That is, the light shielding member 112 need not extend through the sealing layer 115. Even if the light shielding member 112 does not extend through the sealing layer 115, when the light shielding member 112 extends in the sealing layer 115 in a direction intersecting the main surface 121 of the substrate 101, light generated in the light emitting layer in the organic layer 113 is suppressed from leaking to the adjacent pixel 201. That is, it is possible to suppress color mixing between the pixels 201r, 201g, and 201b, thereby improving the color reproducibility of the light emitting device 100′. Furthermore, in the arrangement shown in FIG. 12 as well, the electrode 114 and the light shielding member 112 are electrically connected to each other, and it is possible to supply power to the electrode 114 in the pixel region, thereby suppressing luminance unevenness from the central portion of the pixel region to its peripheral edge portion. Since the light shielding member 112 does not extend through the sealing layer 115, permeation of water in the atmosphere from the surface of the sealing layer 115 via the interface between the light shielding member 112 and the sealing layer 115 can be suppressed more than a case in which the light shielding member 112 extends through the sealing layer 115.

As shown in FIG. 12, an upper end portion 143 of the light shielding member 112 may be arranged at a position farther from the main surface 121 of the substrate 101 than the electrode 114. When the upper end portion 143 of the light shielding member 112 is arranged in the sealing layer 115, the aspect ratio of the light shielding member 112 can be made low. Therefore, a process of forming a hole when forming the light shielding member 112 and a process of embedding the material of the light shielding member 112 in the hole can be easier than in each of the above-described embodiments.

As a method of manufacturing the light emitting device 100′ shown in FIG. 12, before the light shielding member 112 is formed, each of components such as the electrode 108, the organic layer 113, the electrode 114, and the insulating layer 110 and part of the sealing layer 115 are formed. Next, a hole is formed to extend through the insulating layer 110 and part of the sealing layer 115 using the same process as that shown in FIG. 5B, and the light shielding member 112 is formed in this hole. After the formation of the light shielding member 112, an insulating film made of silicon oxide or silicon nitride is deposited, thereby forming the sealing layer 115. After that, the color filter layer 116 and the microlens 117 are formed, thereby forming the light emitting device 100′ shown in FIG. 12.

In the arrangement shown in FIG. 12, the light shielding member 112 is integrally formed. However, the light shielding member 112 may include the two portions 142a and 142b, like the arrangement shown in FIG. 11. The arrangement in which the light shielding member 112 does not extend through the sealing layer 115 is not limited to the arrangement of supplying power to the electrode 114 via the light shielding member 112, as shown in FIG. 12. In the arrangement shown in FIGS. 2 and 3 as well, the upper end portion 143 of the light shielding member 112 may be arranged in the sealing layer 115. In this case as well, after part of the sealing layer 115 is deposited, the light shielding member 112 is formed. Next, an insulating film is deposited to complete the sealing layer 115, thereby arranging the upper end portion 143 of the light shielding member 112 in the sealing layer. For example, by using a transparent electrode as the electrode 108 and providing an insulating layer and a reflective electrode having different film thicknesses between the electrode 108 and the substrate 101, an optical interference structure that amplifies the light intensity of a wavelength different for each pixel 201 may be combined with the light emitting device 100 or 100′.

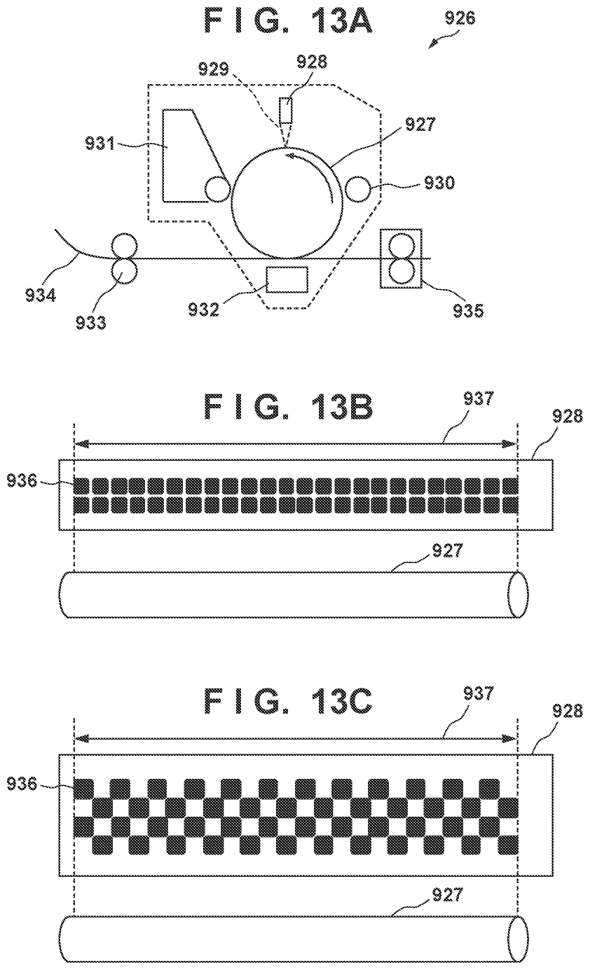

Application examples in which the light emitting device 100 or 100′ according to this embodiment is applied to an image forming device, a display device, a photoelectric conversion device, an electronic apparatus, an illumination device, a moving body, and a wearable device will be described here with reference to FIGS. 13A to 13C to 20A and 20B. Details of the components of the above-described light emitting device 100 or 100′ and modifications will be described first, and the application examples will be described after that. In the following explanation, the component including the electrode 108, the organic layer 113, and the electrode 114 described above will sometimes be expressed as an organic light emitting element. The organic layer 113 and the sealing layer 115 will sometimes be expressed as an organic compound layer and a protection layer, respectively.

The organic light emitting element according to this embodiment includes at least a first electrode and a second electrode, and an organic compound layer arranged between the electrodes. As for the first electrode and the second electrode, one is an anode, and the other is a cathode. In the organic light emitting element according to this embodiment, the organic compound layer may be either a single layer or a stacked body formed by a plurality of layers if it includes a light emitting layer. Here, if the organic compound layer is a stacked body formed by a plurality of layers, the organic compound layer may include a hole injection layer, a hole transport layer, an electron blocking layer, a hole/exciton blocking layer, an electron transport layer, and an electron injection layer in addition to the light emitting layer. The light emitting layer may be a single layer or a stacked body formed by a plurality of layers.

In the organic light emitting element according to this embodiment, at least one layer of the organic compound layer contains an organic metal complex according to this embodiment. More specifically, the organic compound according to this embodiment is contained in one of the light emitting layer, the hole injection layer, the hole transport layer, the electron blocking layer, the hole/exciton blocking layer, the electron transport layer, and the electron injection layer described above. The organic compound according to this embodiment may be contained in the light emitting layer.

In the organic light emitting element according to this embodiment, if the organic compound according to this embodiment is contained in the light emitting layer, the light emitting layer may be a layer made of only the organic compound according to this embodiment or a layer made of the organic metal complex according to this embodiment and another compound. Here, if the light emitting layer is a layer made of the organic metal complex according to this embodiment and another compound, the organic compound according to this embodiment may be used as a host or a guest of the light emitting layer. Alternatively, the organic compound may be used as an assist material that can be contained in the light emitting layer. Here, the host is a compound whose mass ratio is largest in the compounds forming the light emitting layer. The guest is a compound whose mass ratio is smaller than that of the host in the compounds forming the light emitting layer, and is a compound responsible for main light emission. The assist material is a compound whose mass ratio is smaller than that of the host in the compounds forming the light emitting layer, and which assists light emission of the guest. Note that the assist material is also called a second host. The host material can be called a first compound, and the assist material as a second compound.

If the organic compound according to this embodiment is used as the guest of the light emitting layer, the concentration of the guest may be 0.01 mass % (inclusive) to 20 mass % (inclusive) relative to the entire light emitting layer, or may be 0.1 mass % (inclusive) to 10 mass % (inclusive).

The present inventors have made various examinations and found that if the organic compound according to this embodiment is used as the host or guest of the light emitting layer, particularly, as the guest of the light emitting layer, an element that exhibits a light output in high luminance at a high efficiency and has a very high durability can be obtained. The light emitting layer may be a single layer or a multilayer structure. If a light emitting material having another light emission color is contained, the color can be mixed with red that is the light emission color in this embodiment. The multilayer structure means a state in which the light emitting layer and another light emitting layer are stacked. In this case, the light emission color of the organic light emitting element is not limited to red. More specifically, it may be white or an intermediate color. If the color is white, the other light emitting layer emits light in a color other than red, that is, blue or green. As the film forming method, vapor deposition or coating is used to form a film. Details will be described in embodiments to be described later.

The organic metal complex according to this embodiment can be used as the constituent material of the organic compound layer other than the light emitting layer forming the organic light emitting element according to this embodiment. More specifically, the organic metal complex may be used as the constituent material of an electron transport layer, an electron injection layer, a hole transport layer, a hole injection layer, a hole blocking layer, or the like. In this case, the light emission color of the organic light emitting element is not limited to red. More specifically, it may be white or an intermediate color.

Here, in addition to the organic compound according to this embodiment, a conventionally known low molecular and high molecular hole injection compound or hole transport compound, a compound serving as a host, a light emitting compound, an electron injection compound or electron transport compound, or the like can be used together as needed. Examples of these compounds will be described below.

A hole injection/transport material can be a material that has a high hole mobility such that hole injection from the anode is facilitated, and injected holes can be transported to the light emitting layer. It can also be a material having a high glass transition point temperature to suppress degradation of film quality such as crystallization in the organic light emitting element. Examples of low molecular and high molecular materials having hole injection/transport performance are a triarylamine derivative, an arylcarbazole derivative, a phenylenediamine derivative, a stilbene derivative, a phthalocyanine derivative, a porphyrin derivative, a poly(vinyl carbazole), a poly(thiophene), and other conductive polymers. The above-described hole injection/transport material can be used for the electron blocking layer as well. Detailed examples of compounds used as the hole injection/transport material will be shown below. The material is not limited to these, as a matter of course.

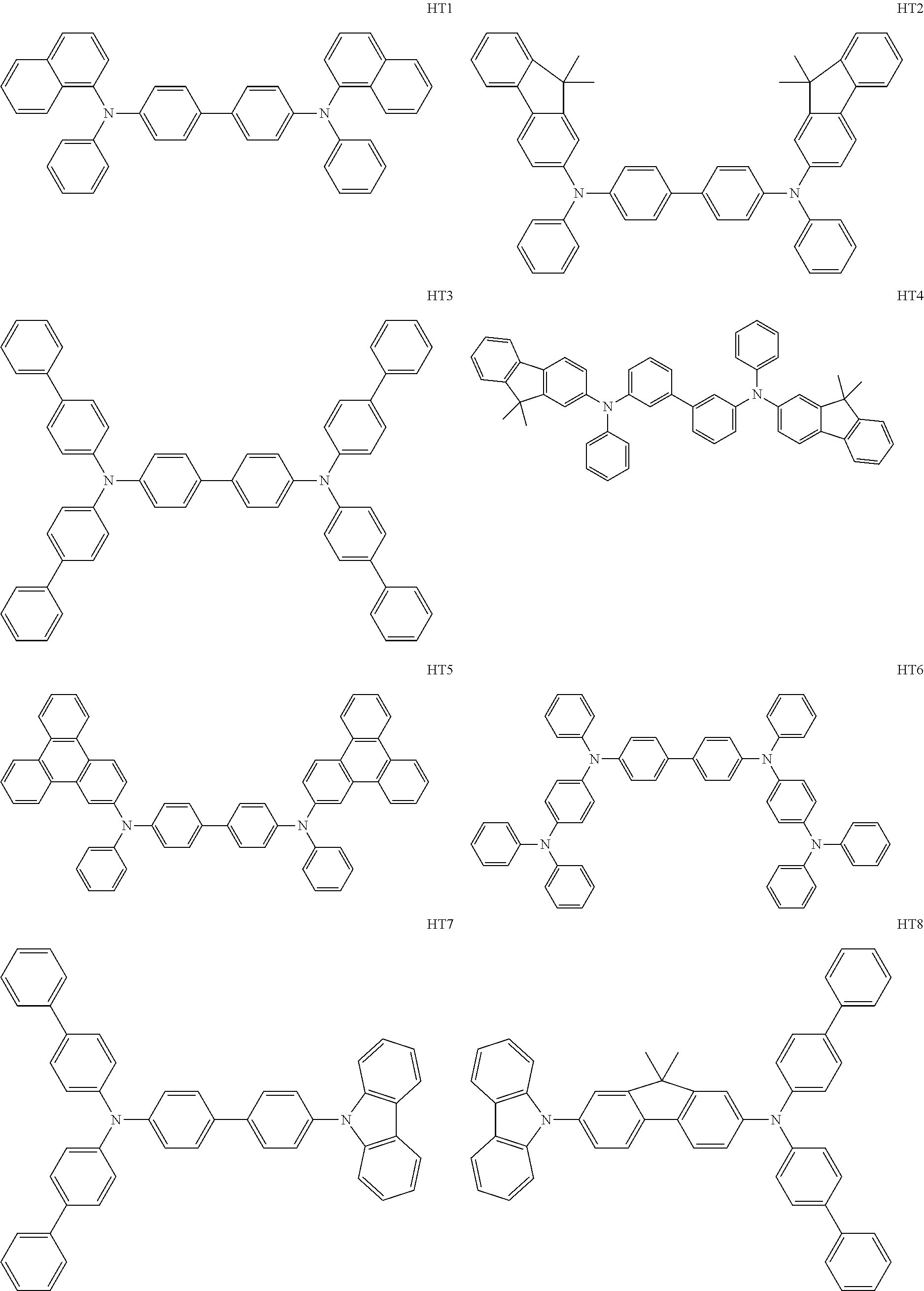

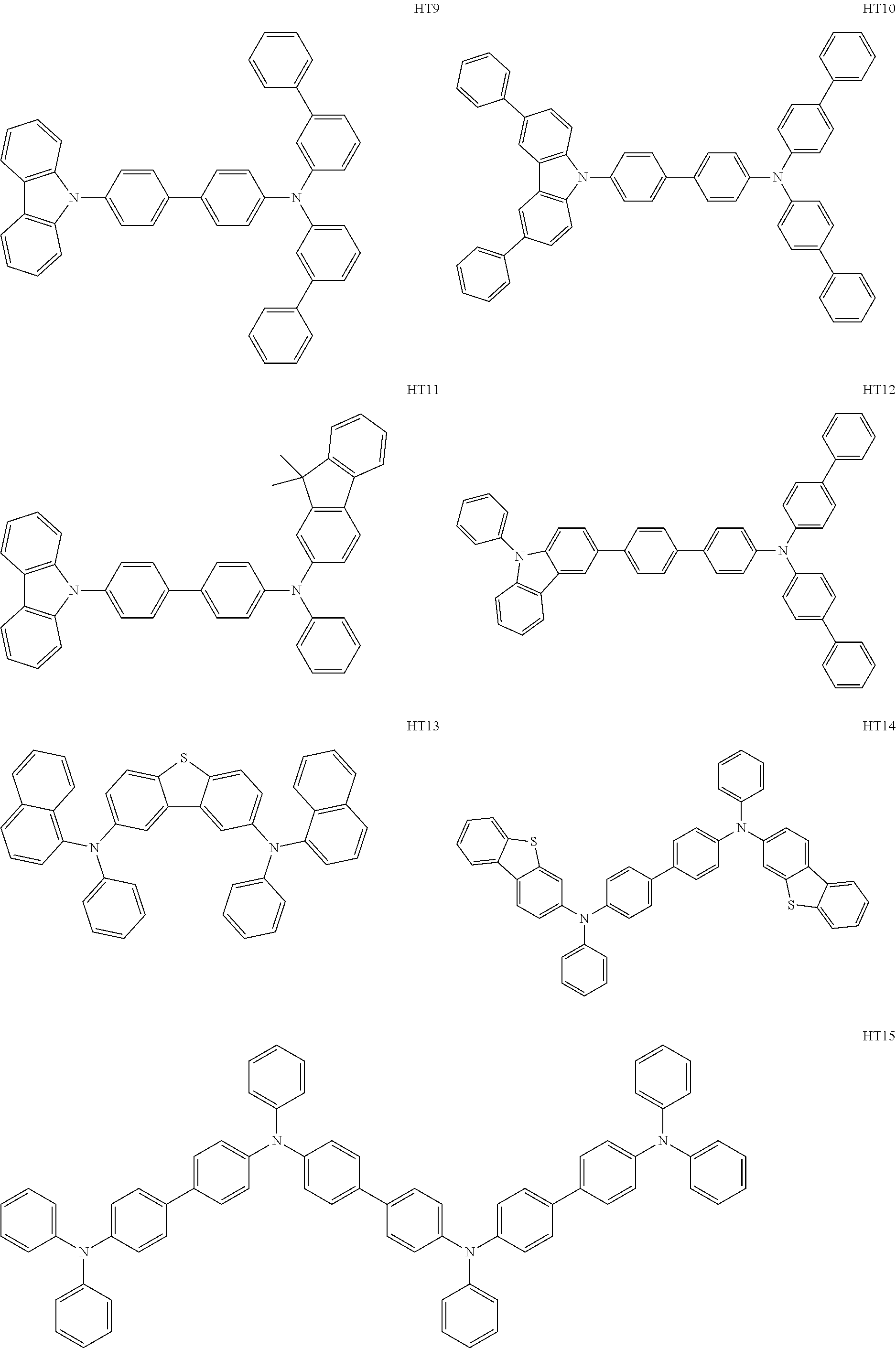

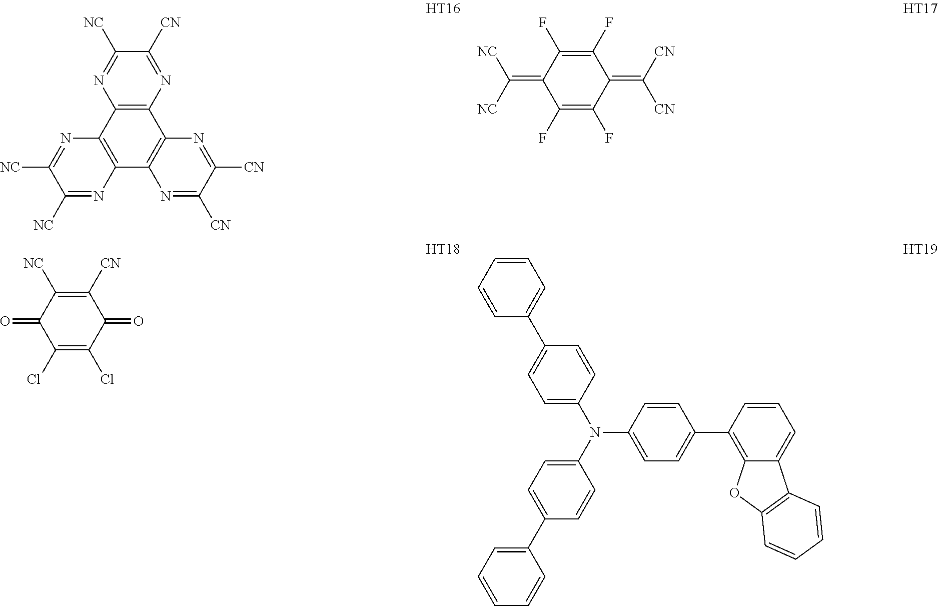

In the hole transport materials, HT16 to HT18 can decrease the driving voltage when used in a layer in contact with the anode. HT16 is widely used in an organic light emitting element. HT2, HT3, HT4, HT5, HT6, HT10, and HT12 can be used in an organic compound layer adjacent to HT16. A plurality of materials may be used in one organic compound layer.

Examples of the light emitting material mainly concerning the light emitting function are condensed-ring compounds (for example, a fluorene derivative, a naphthalene derivative, a pyrene derivative, a perylene derivative, a tetracene derivative, an anthracene derivative, and rubrene), a quinacridone derivative, a coumarin derivative, a stilbene derivative, an organic aluminum complex such as tris(8-quinolinolato)aluminum, an iridium complex, a platinum complex, a rhenium complex, a copper complex, a europium complex, a ruthenium complex, and polymer derivatives such as a poly(phenylenevinylene) derivative, a poly(fluorene) derivative, and a poly(phenylene) derivative.

Detailed examples of compounds used as the light emitting material will be shown below. The material is not limited to these, as a matter of course.

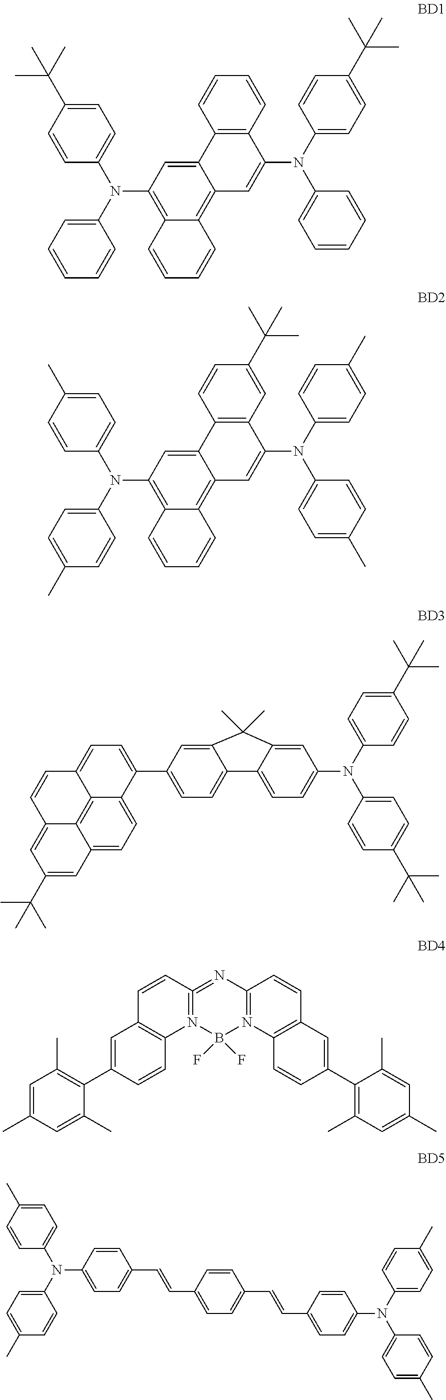

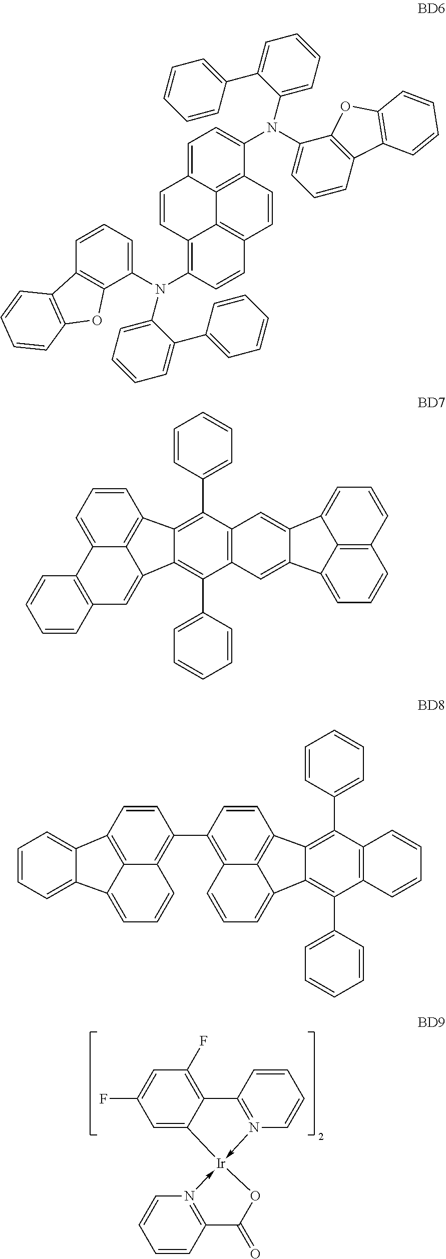

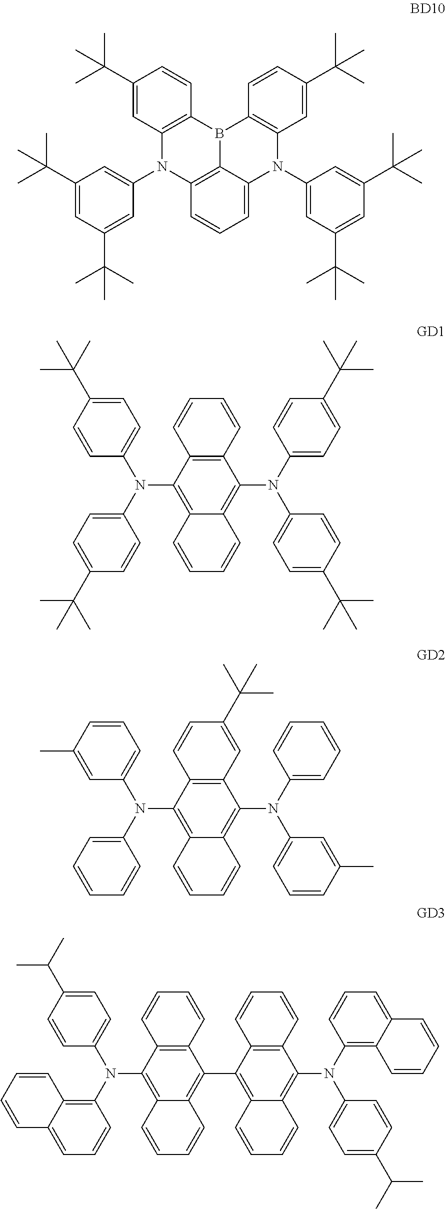

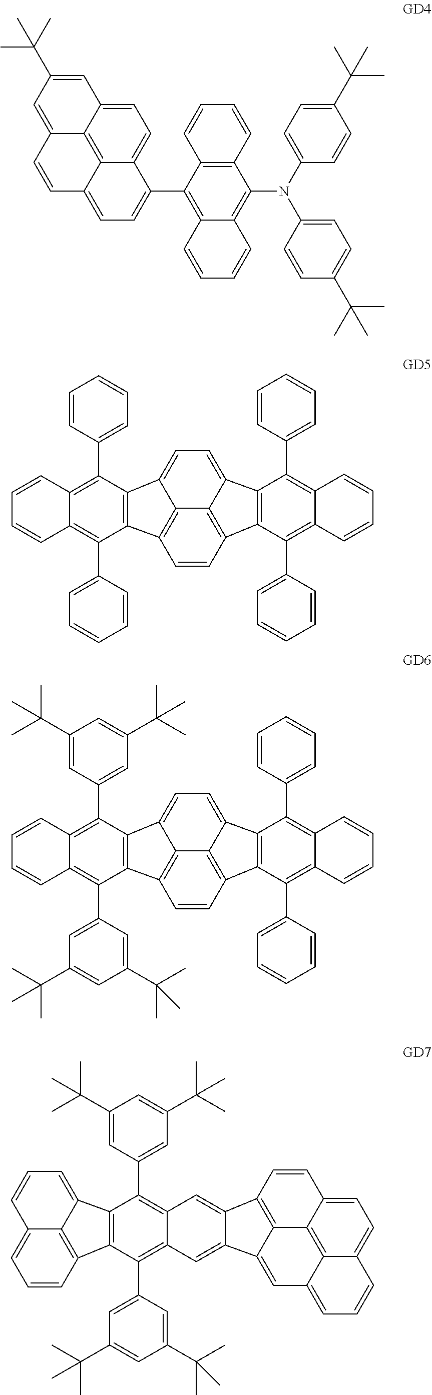

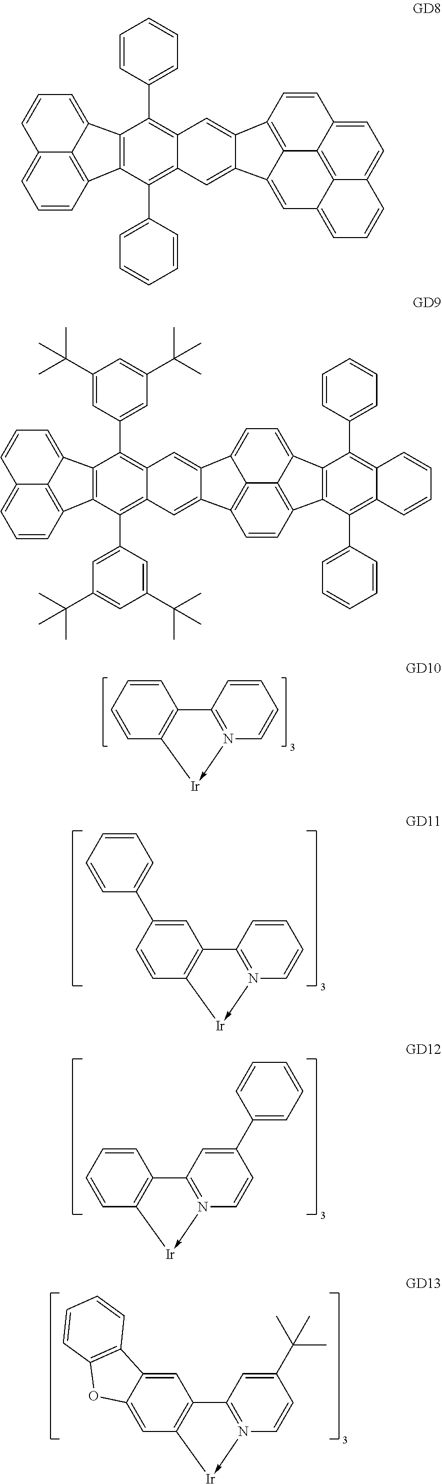

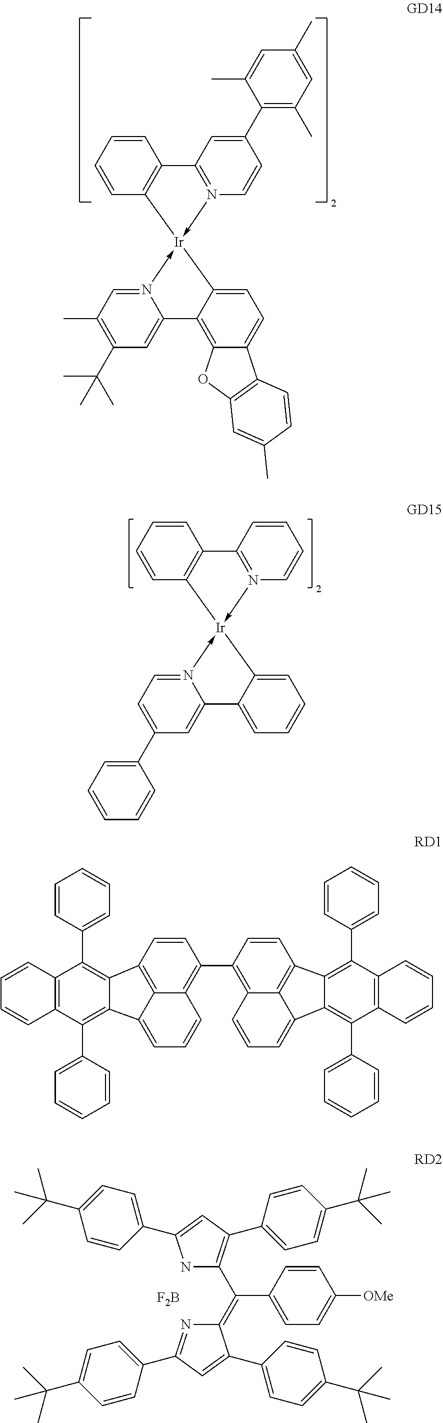

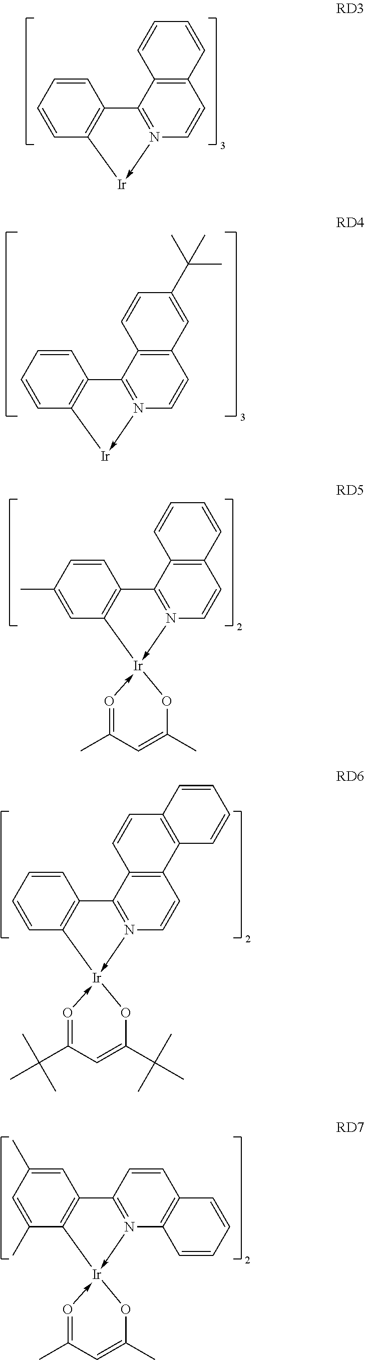

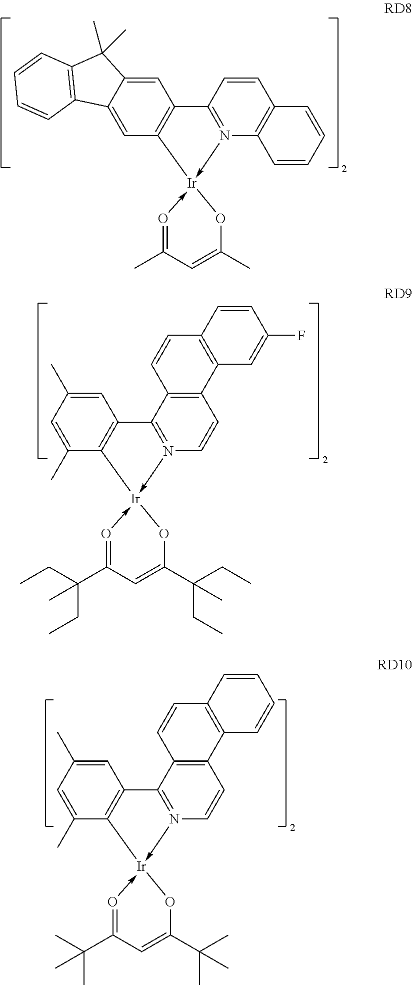

If the light emitting material is a hydrocarbon compound, it is possible to reduce lowering of light emission efficiency caused by exciplex formation or lowering of color purity due to a change of the light emission spectrum of the light emitting material caused by exciplex formation.

The hydrocarbon compound is a compound made of only carbon and hydrogen, and includes BD7, BD8, GD5 to GD9, and RD1 in the compounds exemplified above.

If the light emitting material is a condensed polycyclic compound including a 5-membered ring, oxidation hardly occurs because of a high ionization potential, and a long-life element with high durability can be obtained. This includes BD7, BD8, GD5 to GD9, and RD1 in the compounds exemplified above.

Examples of the light emitting layer host or the light emission assist material contained in the light emitting layer are an aromatic hydrocarbon compound or its derivative, a carbazole derivative, a dibenzofuran derivative, a dibenzothiophene derivative, an organic aluminum complex such as tris(8-quinolinolato)aluminum, and an organic beryllium complex.

Detailed examples of compounds used as the light emitting layer host or the light emission assist material contained in the light emitting layer will be shown below. The material is not limited to these, as a matter of course.

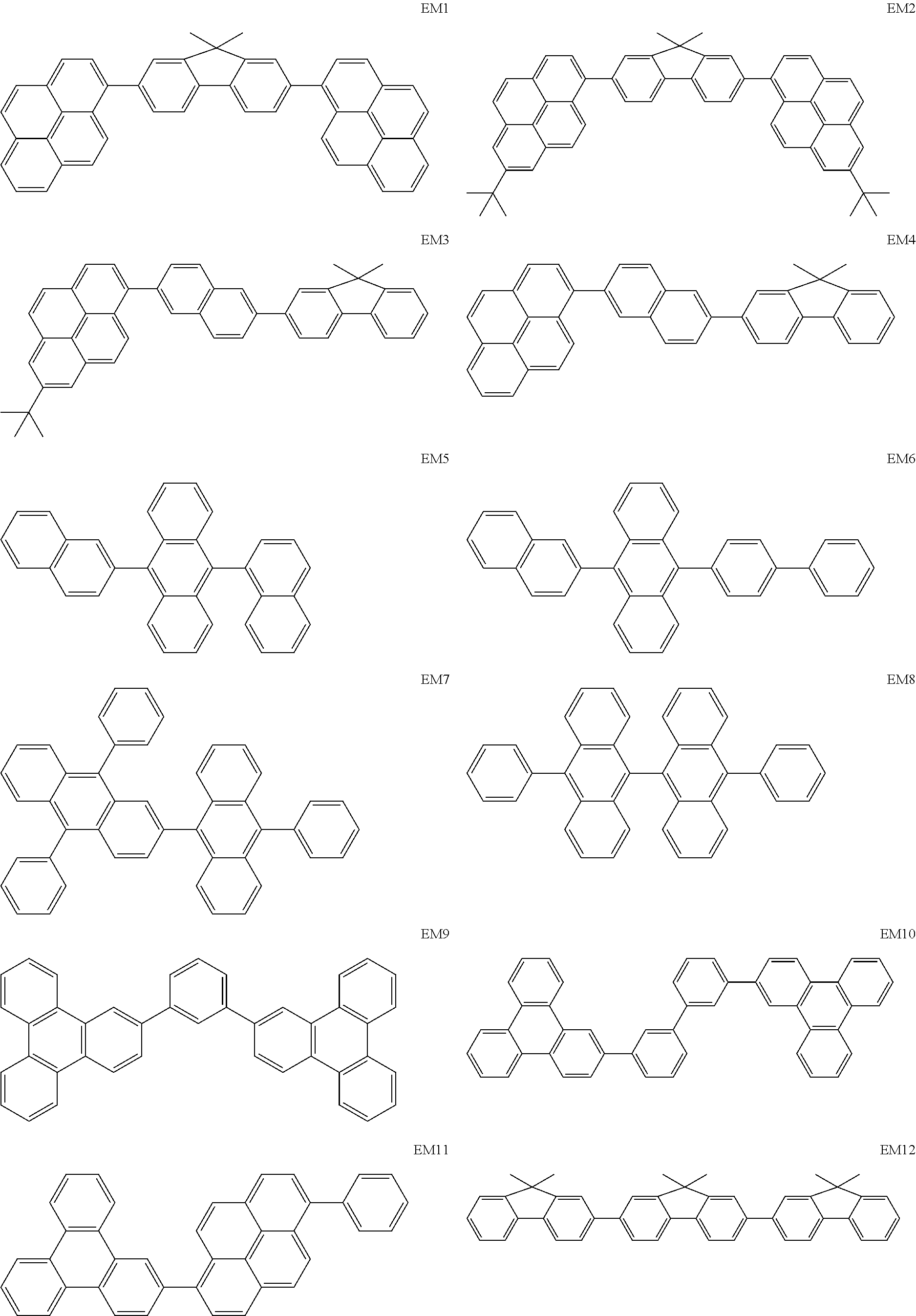

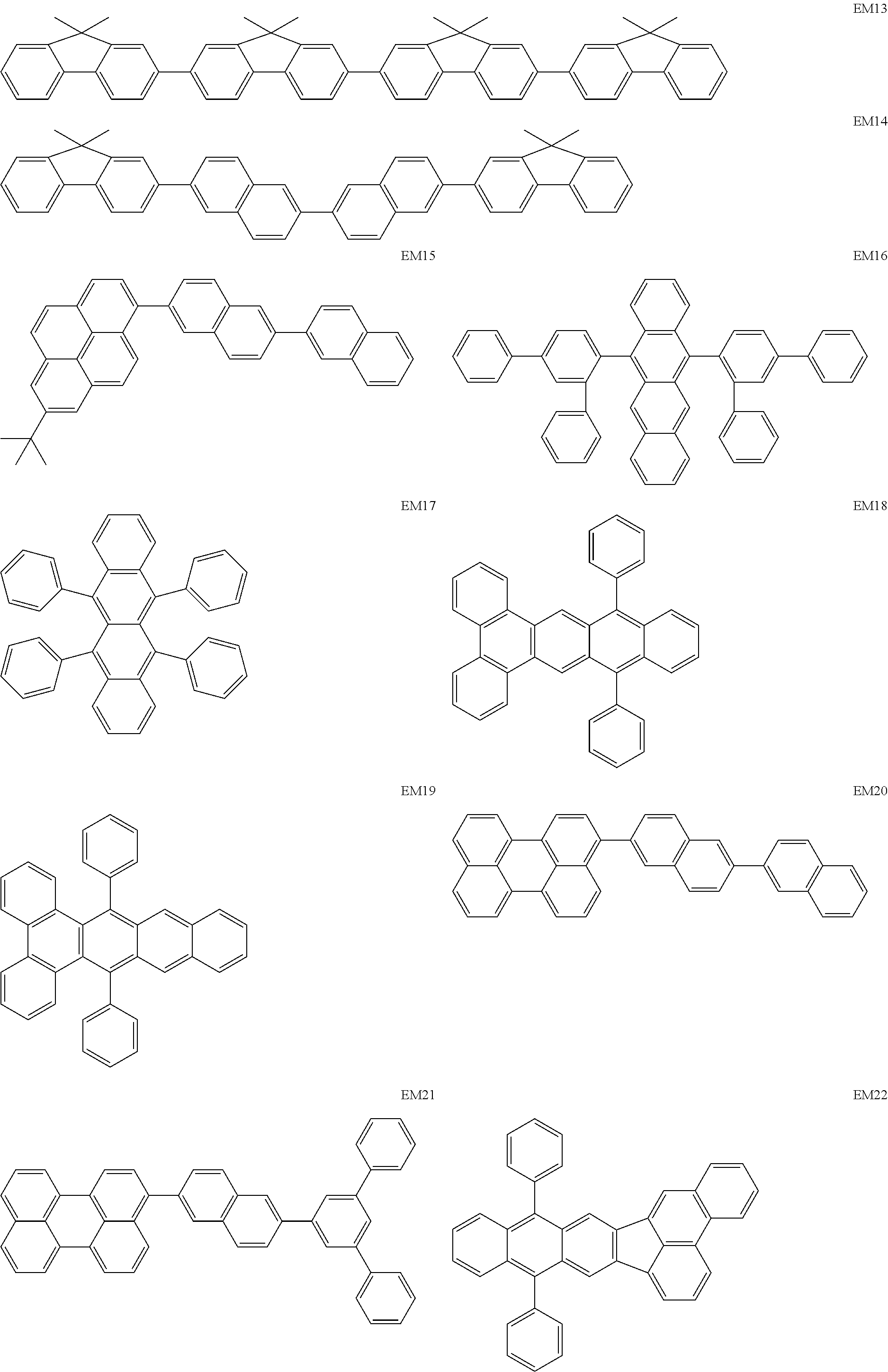

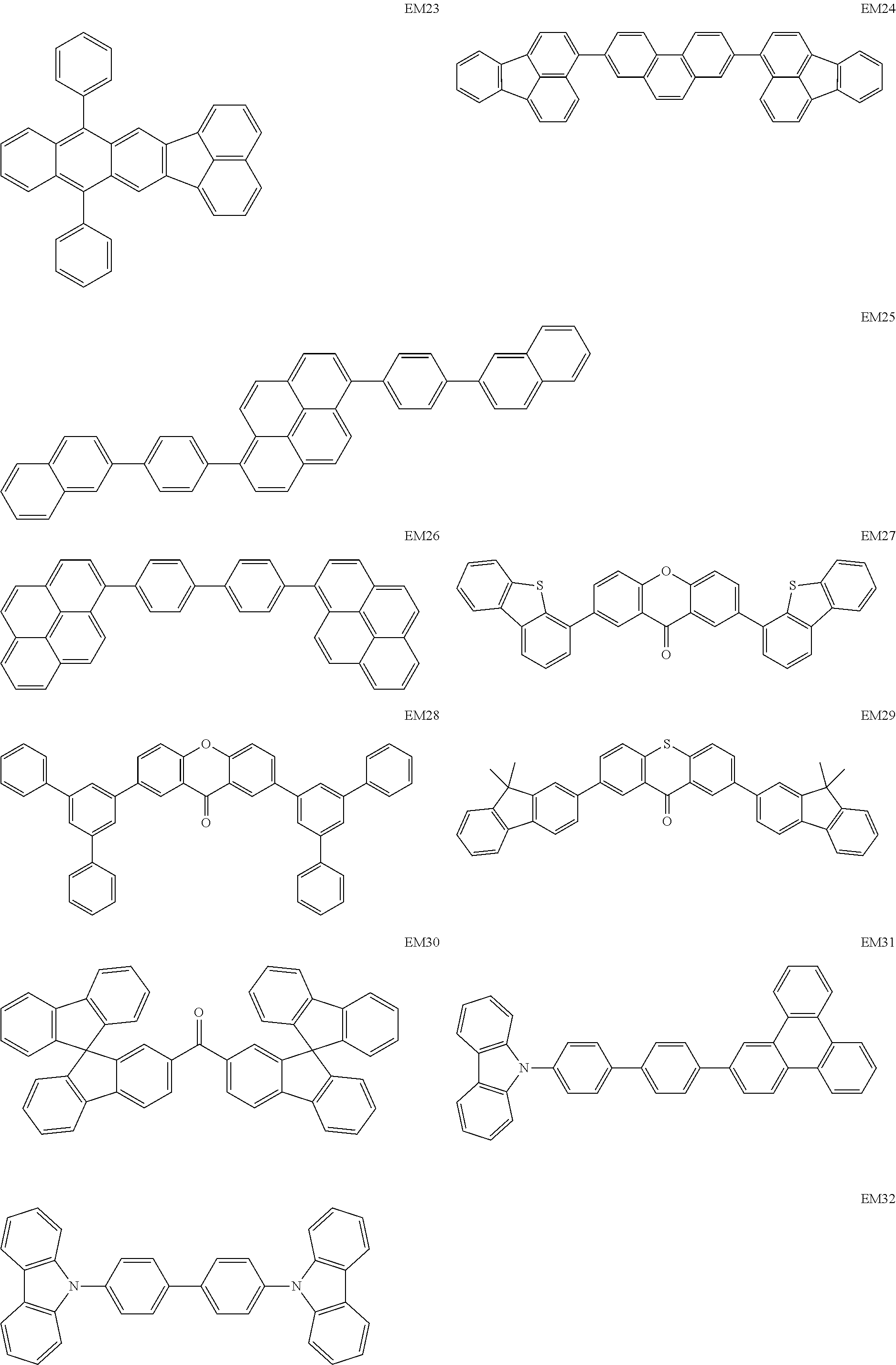

If the host material is a hydrocarbon compound, the compound according to the present invention can readily trap electrons or holes, and therefore, the effect of raising the efficiency becomes large. The hydrocarbon compound is a compound made of only carbon and hydrogen, and includes EM1 to EM12 and EM16 to EM27 in the compounds exemplified above.

The electron transport material can arbitrarily be selected from materials capable of transporting electrons injected from the cathode to the light emitting layer, and is selected in consideration of balance to the hole mobility of the hole transport material. Examples of the material having electron transport performance are an oxadiazole derivative, an oxazole derivative, a pyrazine derivative, a triazole derivative, a triazine derivative, a quinoline derivative, a quinoxaline derivative, a phenanthroline derivative, an organic aluminum complex, and condensed-ring compounds (for example, a fluorene derivative, a naphthalene derivative, a chrysene derivative, and an anthracene derivative). The above-described electron transport material can be used for the hole blocking layer as well.

Detailed examples of compounds used as the electron transport material will be shown below. The material is not limited to these, as a matter of course.

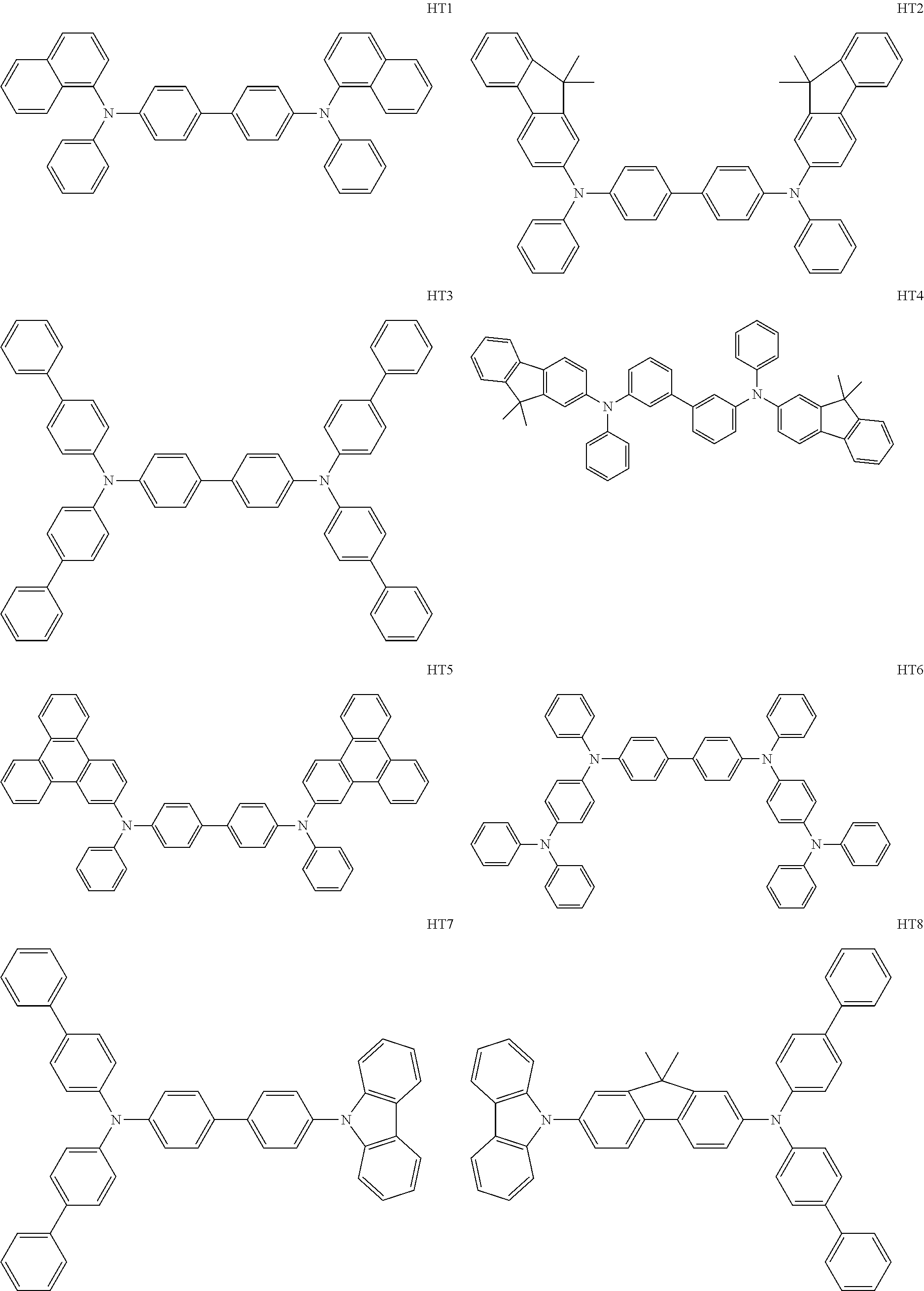

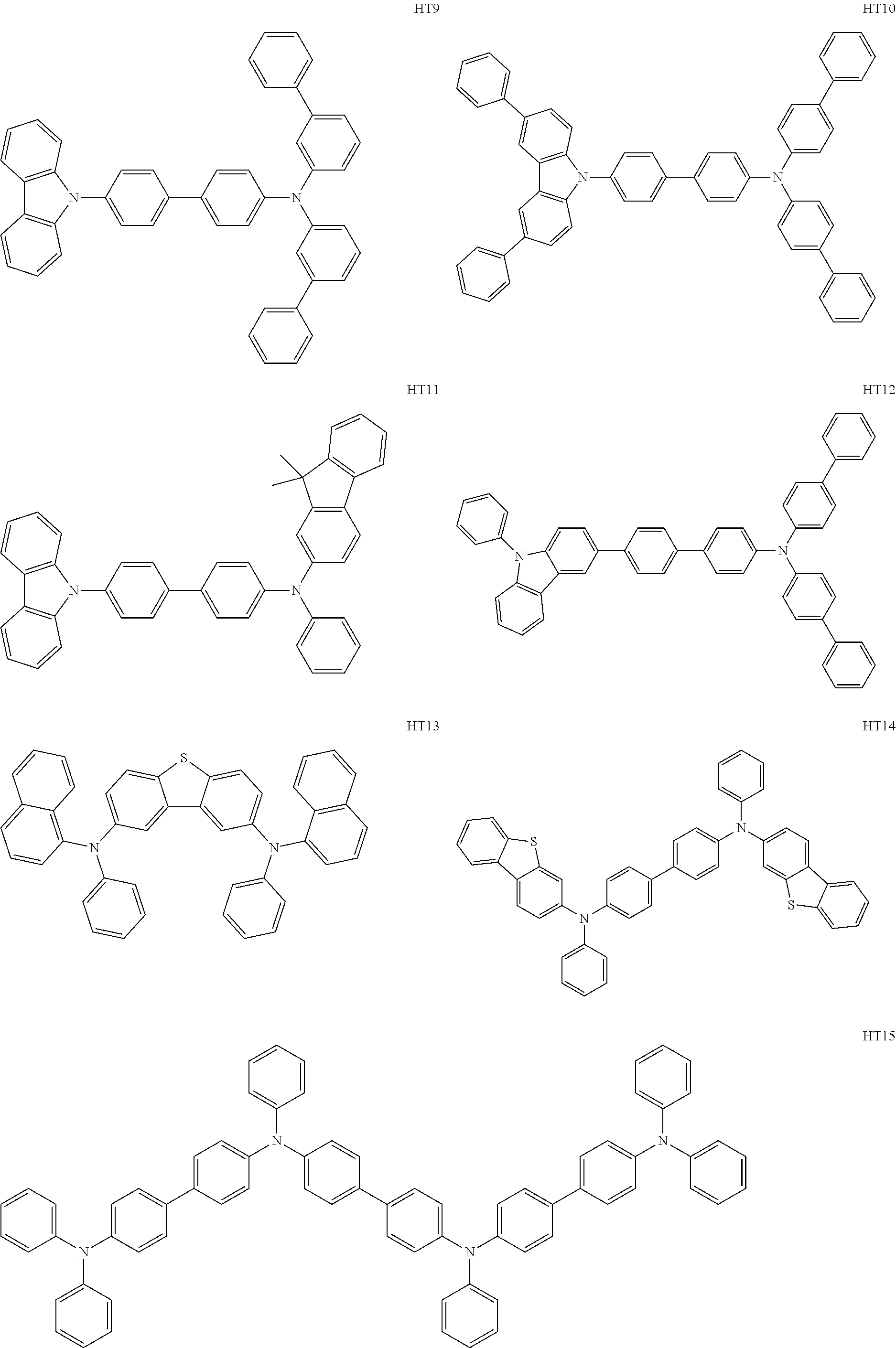

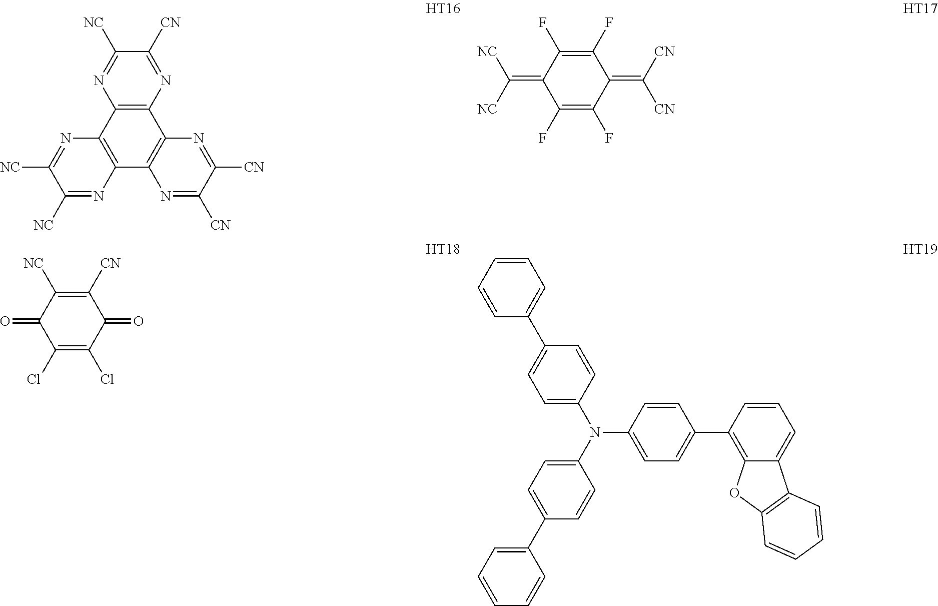

The electron injection material can arbitrarily be selected from materials capable of facilitating electron injection from the cathode, and is selected in consideration of balance to hole injection. The organic compound includes an n-type dopant and a reducible dopant. Examples are a compound containing an alkali metal such as lithium fluoride, a lithium complex such as a lithium-quinolinol complex, a benzo-imidazolidene derivative, an imidazolidene derivative, a fulvalene derivative, and an acridine derivative.

The electron injection material can also be used together with the above-described electron transport material.

The organic light emitting element is formed by forming an insulating layer, a first electrode, an organic compound layer, and a second electrode on a substrate. A protection layer, a color filter, a microlens, and the like may be provided on a cathode. If a color filter is provided, a planarizing layer can be provided between the protection layer and the color filter. The planarizing layer can be made of acrylic resin or the like. The same applies to a case in which a planarizing layer is provided between the color filter and the microlens.

Quartz, glass, a silicon wafer, a resin, a metal, or the like may be used as a substrate. Furthermore, a switching element such as a transistor and a wiring may be provided on the substrate, and an insulating layer may be provided thereon. The insulating layer can be made of any material as long as a contact hole can be formed so that the wiring can be formed between the insulating layer and the first electrode and insulation from the unconnected wiring can be ensured. For example, a resin such as polyimide, silicon oxide, or silicon nitride can be used.

A pair of electrodes can be used as the electrodes. The pair of electrodes can be an anode and a cathode. If an electric field is applied in the direction in which the organic light emitting element emits light, the electrode having a high potential is the anode, and the other is the cathode. It can also be said that the electrode that supplies holes to the light emitting layer is the anode, and the electrode that supplies electrons is the cathode.

As the constituent material of the anode, a material having a work function as large as possible is preferably used. For example, a metal such as gold, platinum, silver, copper, nickel, palladium, cobalt, selenium, vanadium, or tungsten, a mixture containing some of them, an alloy obtained by combining some of them, or a metal oxide such as tin oxide, zinc oxide, indium oxide, indium tin oxide (ITO), or zinc indium oxide can be used. Furthermore, a conductive polymer such as polyaniline, polypyrrole, or polythiophene can also be used.

One of these electrode materials may be used singly, or two or more of them may be used in combination. The anode may be formed by a single layer or a plurality of layers.

When the anode is used as a reflective electrode, for example, chromium, aluminum, silver, titanium, tungsten, molybdenum, an alloy thereof, a stacked layer thereof, or the like can be used. The above materials can function as a reflective film having no role as an electrode. When the anode is used as a transparent electrode, an oxide transparent conductive layer made of indium tin oxide (ITO), indium zinc oxide, or the like can be used, but the present invention is not limited thereto. A photolithography technique can be used to form the electrode.

On the other hand, as the constituent material of the cathode, a material having a small work function is preferably used. Examples of the material include an alkali metal such as lithium, an alkaline earth metal such as calcium, a metal such as aluminum, titanium, manganese, silver, lead, or chromium, and a mixture containing some of them. Alternatively, an alloy obtained by combining these metals can also be used. For example, a magnesium-silver alloy, an aluminum-lithium alloy, an aluminum-magnesium alloy, a silver-copper alloy, a zinc-silver alloy, or the like can be used. A metal oxide such as indium tin oxide (ITO) can also be used. One of these electrode materials may be used singly, or two or more of them may be used in combination. The cathode may have a single-layer structure or a multilayer structure. In particular, silver may be used.

To suppress aggregation of silver, a silver alloy may be used. The ratio of the alloy is not limited as long as aggregation of silver can be suppressed. For example, the ratio between silver and another metal may be 1:1, 3:1, or the like.

The cathode may be a top emission element using an oxide conductive layer made of ITO or the like, or may be a bottom emission element using a reflective electrode made of aluminum (Al) or the like, and is not particularly limited. The method of forming the cathode is not particularly limited, but direct current sputtering or alternating current sputtering is used to provide the good film coverage and easily lower the resistance.

The organic compound layer may be formed by a single layer or a plurality of layers. If the organic compound layer includes a plurality of layers, the layers can be called a hole injection layer, a hole transport layer, an electron blocking layer, a light emitting layer, a hole blocking layer, an electron transport layer, and an electron injection layer in accordance with the functions of the layers. The organic compound layer is mainly formed from an organic compound but may contain inorganic atoms and an inorganic compound. For example, the organic compound layer may contain copper, lithium, magnesium, aluminum, iridium, platinum, molybdenum, zinc, or the like. The organic compound layer can be arranged between the first and second electrodes, and may be arranged in contact with the first and second electrodes.

A protection layer may be provided on the cathode. For example, by adhering glass provided with a moisture absorbing agent on the cathode, permeation of water or the like into the organic compound layer can be suppressed and occurrence of display defects can be suppressed. Furthermore, as another embodiment, a passivation film made of silicon nitride or the like may be provided on the cathode to suppress permeation of water or the like into the organic compound layer. For example, the protection layer can be formed by forming the cathode, transferring it to another chamber without breaking the vacuum, and forming a silicon nitride film having a thickness of 2 μm by the CVD method. The protection layer may be provided using an atomic deposition method (ALD method) after forming a film using the CVD method. The material of the film by the ALD method is not limited but can be silicon nitride, silicon oxide, aluminum oxide, or the like. A silicon nitride film may further be formed by the CVD method on the film formed by the ALD method. The film formed by the ALD method may have a film thickness smaller than that of the film formed by the CVD method. More specifically, the film thickness of the film formed by the ALD method may be 50% or less, or 10% or less.

A color filter may be provided on the protection layer. For example, a color filter considering the size of the organic light emitting element may be provided on another substrate, and this substrate may be bonded to the substrate with the organic light emitting element provided thereon. Alternatively, a color filter may be patterned on the above-described protection layer using a photolithography technique. The color filter can be formed from a polymeric material.

A planarizing layer may be provided between the color filter and the protection layer. The planarizing layer is provided to reduce unevenness of the lower layer. The planarizing layer may be called a material resin layer without limiting the purpose of the layer. The planarizing layer can be formed from an organic compound, and can be made of a low-molecular material or a polymeric material. The polymeric material is more suitable.

The planarizing layers may be provided above and below the color filter, and the same or different materials may be used for them. More specifically, examples of the material include polyvinyl carbazole resin, polycarbonate resin, polyester resin, ABS resin, acrylic resin, polyimide resin, phenol resin, epoxy resin, silicone resin, and urea resin.

The organic light emitting device can include an optical member such as a microlens on the light emission side. The microlens can be made of acrylic resin, epoxy resin, or the like. The microlens can aim to increase the amount of light extracted from the organic light emitting device and control the direction of light to be extracted. The microlens can have a hemispherical shape. If the microlens has a hemispherical shape, among tangents contacting the hemisphere, there is a tangent parallel to the insulating layer, and the contact between the tangent and the hemisphere is the vertex of the microlens. The vertex of the microlens can be decided in the same manner even in an arbitrary sectional view. That is, among tangents contacting the semicircle of the microlens in a sectional view, there is a tangent parallel to the insulating layer, and the contact between the tangent and the semicircle is the vertex of the microlens.

Furthermore, the middle point of the microlens can also be defined. In the section of the microlens, a line segment from a point at which an arc shape ends to a point at which another arc shape ends is assumed, and the middle point of the line segment can be called the middle point of the microlens. A section for determining the vertex and the middle point may be a section perpendicular to the insulating layer.

A counter substrate can be provided on the planarizing layer. The counter substrate is called a counter substrate because it is provided at a position corresponding to the above-described substrate. The constituent material of the counter substrate can be the same as that of the above-described substrate. When the above-described substrate is the first substrate, the counter substrate can be the second substrate.

The organic compound layer (hole injection layer, hole transport layer, electron blocking layer, light emitting layer, hole blocking layer, electron transport layer, electron injection layer, and the like) forming the organic light emitting element according to an embodiment of the present invention is formed by the method to be described below.

The organic compound layer forming the organic light emitting element according to the embodiment of the present invention can be formed by a dry process using a vacuum deposition method, an ionization deposition method, a sputtering method, a plasma method, or the like. Instead of the dry process, a wet process that forms a layer by dissolving a solute in an appropriate solvent and using a well-known coating method (for example, a spin coating method, a dipping method, a casting method, an LB method, an inkjet method, or the like) can be used.

Here, when the layer is formed by a vacuum deposition method, a solution coating method, or the like, crystallization or the like hardly occurs and excellent temporal stability is obtained. Furthermore, when the layer is formed using a coating method, it is possible to form the film in combination with a suitable binder resin.

Examples of the binder resin include polyvinyl carbazole resin, polycarbonate resin, polyester resin, ABS resin, acrylic resin, polyimide resin, phenol resin, epoxy resin, silicone resin, and urea resin. However, the binder resin is not limited to them.

One of these binder resins may be used singly as a homopolymer or a copolymer, or two or more of them may be used in combination. Furthermore, additives such as a well-known plasticizer, antioxidant, and an ultraviolet absorber may also be used as needed.

The light emitting device can include a pixel circuit connected to the light emitting element. The pixel circuit may be an active matrix circuit that individually controls light emission of the first and second light emitting elements. The active matrix circuit may be a voltage or current programing circuit. A driving circuit includes a pixel circuit for each pixel. The pixel circuit can include a light emitting element, a transistor for controlling light emission luminance of the light emitting element, a transistor for controlling a light emission timing, a capacitor for holding the gate voltage of the transistor for controlling the light emission luminance, and a transistor for connection to GND without intervention of the light emitting element.

The light emitting device includes a display region and a peripheral region arranged around the display region. The light emitting device includes the pixel circuit in the display region and a display control circuit in the peripheral region. The mobility of the transistor forming the pixel circuit may be smaller than that of a transistor forming the display control circuit.

The slope of the current-voltage characteristic of the transistor forming the pixel circuit may be smaller than that of the current-voltage characteristic of the transistor forming the display control circuit. The slope of the current-voltage characteristic can be measured by a so-called Vg-Ig characteristic.

The transistor forming the pixel circuit is a transistor connected to the light emitting element such as the first light emitting element.

The organic light emitting device includes a plurality of pixels. Each pixel includes sub-pixels (corresponding to the above-described pixels 201) that emit light components of different colors. The sub-pixels include, for example, R, G, and B emission colors, respectively.

In each pixel, a region also called a pixel opening emits light. This region is the same as the first region. The pixel opening can have a size of 5 μm (inclusive) to 15 μm (inclusive). More specifically, the pixel opening can have a size of 11 μm, 9.5 μm, 7.4 μm, 6.4 μm, or the like.

A distance between the sub-pixels can be 10 μm or less, and can be, more specifically, 8 μm, 7.4 μm, or 6.4 μm.

The pixels can have a known arrangement form in a plan view. For example, the pixels may have a stripe arrangement, a delta arrangement, a pentile arrangement, or a Bayer arrangement. The shape of each sub-pixel in a plan view may be any known shape. For example, a quadrangle such as a rectangle or a rhombus, a hexagon, or the like may be possible. A shape which is not a correct shape but is close to a rectangle is included in a rectangle. The shape of the sub-pixel and the pixel arrangement can be used in combination.

The organic light emitting element according to an embodiment of the present invention can be used as a constituent member of a display device or an illumination device. In addition, the organic light emitting element is applicable to the exposure light source of an electrophotographic image forming device, the backlight of a liquid crystal display device, a light emitting device including a color filter in a white light source, and the like.

The display device may be an image information processing device that includes an image input unit for inputting image information from an area CCD, a linear CCD, a memory card, or the like, and an information processing unit for processing the input information, and displays the input image on a display unit.

In addition, a display unit included in an image capturing device or an inkjet printer can have a touch panel function. The driving type of the touch panel function may be an infrared type, a capacitance type, a resistive film type, or an electromagnetic induction type, and is not particularly limited. The display device may be used for the display unit of a multifunction printer.

The light emitting device according to the embodiment will be described next with reference to the accompanying drawings.

FIGS. 13A to 13C are schematic views showing an example of an image forming device using the light emitting device 100 or 100′ of this embodiment. An image forming device 926 shown in FIG. 13A includes a photosensitive member 927, an exposure light source 928, a developing unit 931, a charging unit 930, a transfer device 932, a conveyance unit 933 (a conveyance roller in the arrangement shown in FIG. 13A), and a fixing device 935.

Light 929 is emitted from the exposure light source 928, and an electrostatic latent image is formed on the surface of the photosensitive member 927. The light emitting device 100 or 100′ according to this embodiment can be applied to the exposure light source 928. The developing unit 931 can function as a developing device that includes a toner or the like as a developing agent and applies the developing agent to the exposed photosensitive member 927. The charging unit 930 charges the photosensitive member 927. The transfer device 932 transfers the developed image to a print medium 934. The conveyance unit 933 conveys the print medium 934. The print medium 934 can be, for example, paper or a film. The fixing device 935 fixes the image formed on the print medium.

Each of FIGS. 13B and 13C is a schematic view showing a plurality of light emitting units 936 arranged in the exposure light source 928 along the longitudinal direction of a long substrate. The light emitting device 100 or 100′ according to this embodiment can be applied to each of the light emitting units 936. That is, the plurality of pixels 201 arranged in the display region are arranged along the longitudinal direction of the substrate. A direction 937 is a direction parallel to the axis of the photosensitive member 927. This column direction matches the direction of the axis upon rotating the photosensitive member 927. This direction 937 can also be referred to as the long-axis direction of the photosensitive member 927.

FIG. 13B shows a form in which the light emitting units 936 are arranged along the long-axis direction of the photosensitive member 927. FIG. 13C shows a form, which is a modification of the arrangement of the light emitting units 936 shown in FIG. 13B, in which the light emitting units 936 are arranged in the column direction alternately between the first column and the second column. The light emitting units 936 are arranged at different positions in the row direction between the first column and the second column. In the first column, the plurality of light emitting units 936 are arranged spaced apart from each other. In the second column, the light emitting unit 936 is arranged at the position corresponding to the space between the light emitting units 936 in the first column. Furthermore, in the row direction, the plurality of light emitting units 936 are arranged spaced apart from each other. The arrangement of the light emitting units 936 shown in FIG. 13C can be referred to as, for example, an arrangement in a grid pattern, an arrangement in a staggered pattern, or an arrangement in a checkered pattern.

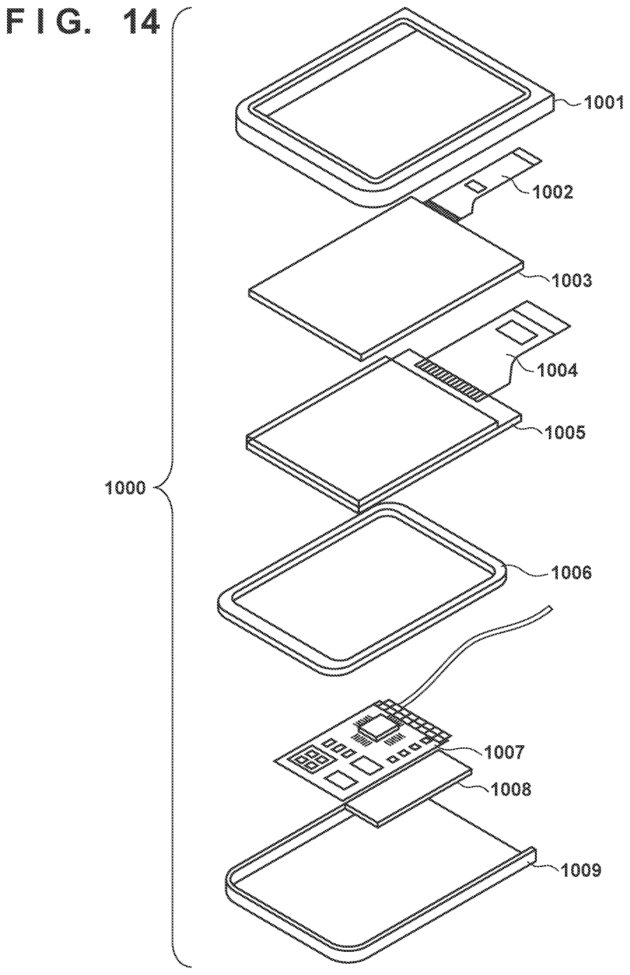

FIG. 14 is a schematic view showing an example of the display device using the light emitting device 100 or 100′ of this embodiment. A display device 1000 can include a touch panel 1003, a display panel 1005, a frame 1006, a circuit board 1007, and a battery 1008 between an upper cover 1001 and a lower cover 1009. Flexible printed circuits (FPCs) 1002 and 1004 are respectively connected to the touch panel 1003 and the display panel 1005. Active elements such as transistors are arranged on the circuit board 1007. The battery 1008 is unnecessary if the display device 1000 is not a portable apparatus. Even when the display device 1000 is a portable apparatus, the battery 1008 need not be provided at this position. The light emitting device 100 or 100′ according to this embodiment can be applied to the display panel 1005. The display region of the light emitting device 100 or 100′ functioning as the display panel 1005 is connected to the active elements such as transistors arranged on the circuit board 1007 and operates.

The display device 1000 shown in FIG. 14 can be used for a display of a photoelectric conversion device (image capturing device) including an optical unit having a plurality of lenses, and an image sensor for receiving light having passed through the optical unit and photoelectrically converting the light into an electric signal. The photoelectric conversion device can include a display for displaying information acquired by the image sensor. In addition, the display can be either a display unit exposed outside the photoelectric conversion device, or a display unit arranged in the finder. The photoelectric conversion device can be a digital camera or a digital video camera.

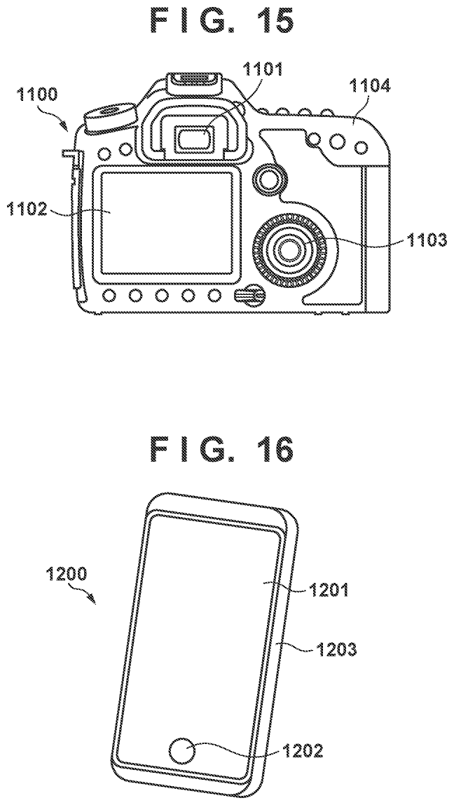

FIG. 15 is a schematic view showing an example of the photoelectric conversion device using the light emitting device 100 or 100′ of this embodiment. A photoelectric conversion device 1100 can include a viewfinder 1101, a rear display 1102, an operation unit 1103, and a housing 1104. The photoelectric conversion device 1100 can also be called an image capturing device. The light emitting device 100 or 100′ according to this embodiment can be applied to the viewfinder 1101 or the rear display 1102 as a display unit. In this case, the light emitting device 100 or 100′ can display not only an image to be captured but also environment information, image capturing instructions, and the like. Examples of the environment information are the intensity and direction of external light, the moving velocity of an object, and the possibility that an object is covered with an obstacle.

The timing suitable for image capturing is a very short time in many cases, so the information is preferably displayed as soon as possible. Therefore, the light emitting device 100 or 100′ containing the organic light emitting material such as an organic EL element in the light emitting layer can be used for the viewfinder 1101 or the rear display 1102. This is so because the organic light emitting material has a high response speed. The light emitting device 100 or 100′ using the organic light emitting material can be used for the apparatuses that require a high display speed more preferably than for the liquid crystal display device.

The photoelectric conversion device 1100 includes an optical unit (not shown). This optical unit has a plurality of lenses, and forms an image on a photoelectric conversion element (not shown) that receives light having passed through the optical unit and is accommodated in the housing 1104. The focal points of the plurality of lenses can be adjusted by adjusting the relative positions. This operation can also automatically be performed.

The light emitting device 100 or 100′ may be applied to a display of an electronic apparatus. At this time, the display can have both a display function and an operation function. Examples of the portable terminal are a portable phone such as a smartphone, a tablet, and a head mounted display.

FIG. 16 is a schematic view showing an example of an electronic apparatus using the light emitting device 100 or 100′ of this embodiment. An electronic apparatus 1200 includes a display 1201, an operation unit 1202, and a housing 1203. The housing 1203 can accommodate a circuit, a printed board having this circuit, a battery, and a communication unit. The operation unit 1202 can be a button or a touch-panel-type reaction unit. The operation unit 1202 can also be a biometric authentication unit that performs unlocking or the like by authenticating the fingerprint. The portable apparatus including the communication unit can also be regarded as a communication apparatus. The light emitting device 100 or 100′ according to this embodiment can be applied to the display 1201.

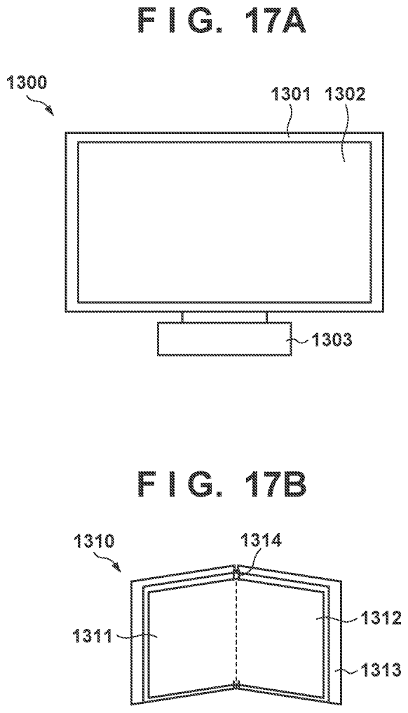

FIGS. 17A and 17B are schematic views showing examples of the display device using the light emitting device 100 or 100′ of this embodiment. FIG. 17A shows a display device such as a television monitor or a PC monitor. A display device 1300 includes a frame 1301 and a display 1302. The light emitting device 100 or 100′ according to this embodiment can be applied to the display 1302. The display device 1300 can include a base 1303 that supports the frame 1301 and the display 1302. The base 1303 is not limited to the form shown in FIG. 17A. For example, the lower side of the frame 1301 may also function as the base 1303. In addition, the frame 1301 and the display 1302 can be bent. The radius of curvature in this case can be 5,000 mm (inclusive) to 6,000 mm (inclusive).

FIG. 17B is a schematic view showing another example of the display device using the light emitting device 100 or 100′ of this embodiment. A display device 1310 shown in FIG. 17B can be folded, and is a so-called foldable display device. The display device 1310 includes a first display 1311, a second display 1312, a housing 1313, and a bending point 1314. The light emitting device 100 or 100′ according to this embodiment can be applied to each of the first display 1311 and the second display 1312. The first display 1311 and the second display 1312 can also be one seamless display device. The first display 1311 and the second display 1312 can be divided by the bending point. The first display 1311 and the second display 1312 can display different images, and can also display one image together.

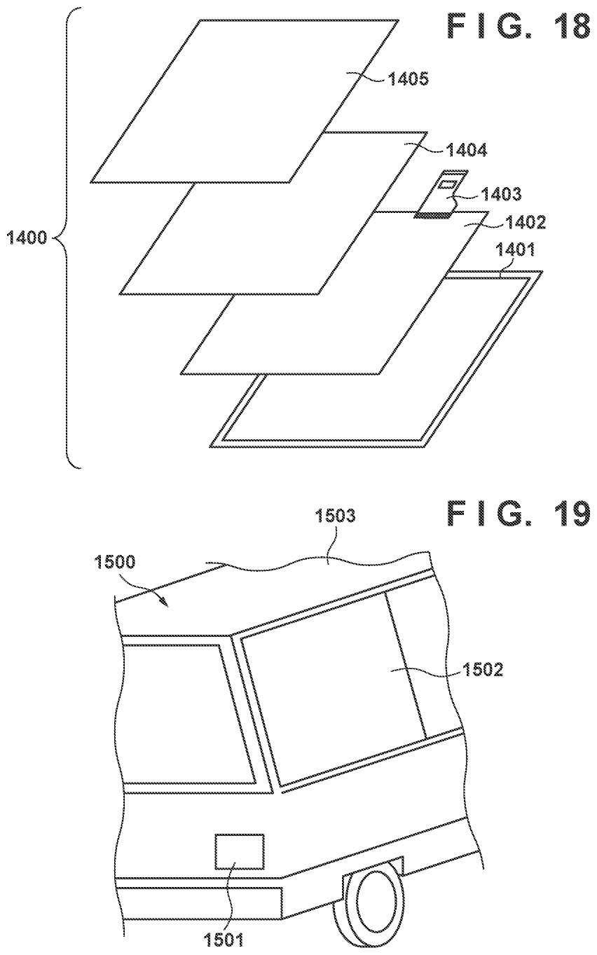

FIG. 18 is a schematic view showing an example of the illumination device using the light emitting device 100 or 100′ of this embodiment. An illumination device 1400 can include a housing 1401, a light source 1402, a circuit board 1403, an optical film 1404, and a light diffuser 1405. The light emitting device 100 or 100′ according to this embodiment can be applied to the light source 1402. The optical film 1404 can be a filter that improves the color rendering of the light source. When performing lighting-up or the like, the light diffuser 1405 can throw the light of the light source over a broad range by effectively diffusing the light. The illumination device can also include a cover on the outermost portion, as needed. The illumination device 1400 can include both or one of the optical film 1404 and the light diffuser 1405.

The illumination device 1400 is, for example, a device for illuminating the interior of the room. The illumination device 1400 can emit white light, natural white light, or light of any color from blue to red. The illumination device 1400 can also include a light control circuit for controlling these light components. The illumination device 1400 can also include a power supply circuit connected to the light emitting device 100 or 100′ functioning as the light source 1402. The power supply circuit is a circuit for converting an AC voltage into a DC voltage. White has a color temperature of 4,200 K, and natural white has a color temperature of 5,000 K. The illumination device 1400 may also include a color filter. In addition, the illumination device 1400 can include a heat radiation unit. The heat radiation unit radiates the internal heat of the device to the outside of the device, and examples are a metal having a high specific heat and liquid silicon.

FIG. 19 is a schematic view of an automobile having a taillight as an example of a vehicle lighting appliance using the light emitting device 100 or 100′ of this embodiment. An automobile 1500 has a taillight 1501, and can have a form in which the taillight 1501 is turned on when performing a braking operation or the like. The light emitting device 100 or 100′ of this embodiment can be used as a headlight serving as a vehicle lighting appliance. The automobile is an example of a moving body, and the moving body may be a ship, a drone, an aircraft, a railroad car, an industrial robot, or the like. The moving body may include a main body and a lighting appliance provided in the main body. The lighting appliance may be used to make a notification of the current position of the main body.

The light emitting device 100 or 100′ according to this embodiment can be applied to the taillight 1501. The taillight 1501 can include a protection member for protecting the light emitting device 100 or 100′ functioning as the taillight 1501. The material of the protection member is not limited as long as the material is a transparent material with a strength that is high to some extent, and an example is polycarbonate. A furandicarboxylic acid derivative, an acrylonitrile derivative, or the like may be mixed in polycarbonate.

The automobile 1500 can include a vehicle body 1503, and a window 1502 attached to the vehicle body 1503. This window can be a window for checking the front and back of the automobile, and can also be a transparent display. For this transparent display, the light emitting device 100 or 100′ according to this embodiment may be used. In this case, the constituent materials of the electrodes and the like of the light emitting device 100 or 100′ are formed by transparent members.

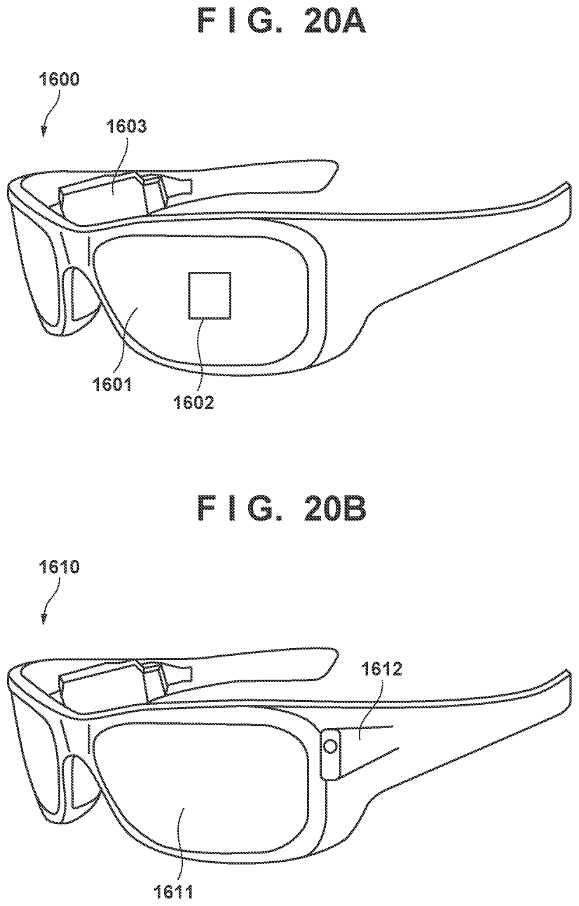

Further application examples of the light emitting device 100 or 100′ according to this embodiment will be described with reference to FIGS. 20A and 20B. The light emitting device 100 or 100′ can be applied to a system that can be worn as a wearable device such as smartglasses, an HMD (Head Mounted Display), or a smart contact lens. An image capturing display device used for such application examples includes an image capturing device capable of photoelectrically converting visible light and a light emitting device capable of emitting visible light.

Glasses 1600 (smartglasses) according to one application example will be described with reference to FIG. 20A. An image capturing device 1602 such as a CMOS sensor or an SPAD is provided on the surface side of a lens 1601 of the glasses 1600. In addition, the light emitting device 100 or 100′ according to this embodiment is provided on the back surface side of the lens 1601.

The glasses 1600 further include a control device 1603. The control device 1603 functions as a power supply that supplies electric power to the image capturing device 1602 and the light emitting device 100 or 100′ according to each embodiment. In addition, the control device 1603 controls the operations of the image capturing device 1602 and the light emitting device 100 or 100′. An optical system configured to condense light to the image capturing device 1602 is formed on the lens 1601.

Glasses 1610 (smartglasses) according to one application example will be described with reference to FIG. 20B. The glasses 1610 include a control device 1612, and an image capturing device corresponding to the image capturing device 1602 and the light emitting device 100 or 100′ are mounted on the control device 1612. The image capturing device in the control device 1612 and an optical system configured to project light emitted from the light emitting device 100 or 100′ are formed in a lens 1611, and an image is projected to the lens 1611. The control device 1612 functions as a power supply that supplies electric power to the image capturing device and the light emitting device 100 or 100′, and controls the operations of the image capturing device and the light emitting device 100 or 100′. The control device 1612 may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a planar view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The light emitting device 100 or 100′ according to the embodiment of the present invention can include an image capturing device including a light receiving element, and control a displayed image based on the line-of-sight information of the user from the image capturing device.

More specifically, the light emitting device 100 or 100′ decides a first visual field region at which the user is gazing and a second visual field region other than the first visual field region based on the line-of-sight information. The first visual field region and the second visual field region may be decided by the control device of the light emitting device 100 or 100′, or those decided by an external control device may be received. In the display region of the light emitting device 100 or 100′, the display resolution of the first visual field region may be controlled to be higher than the display resolution of the second visual field region. That is, the resolution of the second visual field region may be lower than that of the first visual field region.

In addition, the display region includes a first display region and a second display region different from the first display region, and a region of higher priority is decided from the first display region and the second display region based on line-of-sight information. The first display region and the second display region may be decided by the control device of the light emitting device 100 or 100′, or those decided by an external control device may be received. The resolution of the region of higher priority may be controlled to be higher than the resolution of the region other than the region of higher priority. That is, the resolution of the region of relatively low priority may be low.

Note that AI may be used to decide the first visual field region or the region of higher priority. The AI may be a model configured to estimate the angle of the line of sight and the distance to a target ahead the line of sight from the image of the eyeball using the image of the eyeball and the direction of actual viewing of the eyeball in the image as supervised data. The AI program may be held by the light emitting device 100 or 100′, the image capturing device, or an external device. If the external device holds the AI program, it is transmitted to the light emitting device 100 or 100′ via communication.

When performing display control based on line-of-sight detection, smartglasses further including an image capturing device configured to capture the outside can be applied. The smartglasses can display captured outside information in real time.

This specification includes the following light emitting device, display device, photoelectric conversion device, electronic apparatus, illumination device, and moving body.

Item 1. A light emitting device in which a plurality of light emitting elements sealed by a sealing layer are arranged on a main surface of a substrate,

wherein each of the plurality of light emitting elements comprises a first electrode arranged between the substrate and the sealing layer, a second electrode arranged between the first electrode and the sealing layer, and an organic layer including a light emitting layer arranged between the first electrode and the second electrode, and

the light emitting device further comprises

an insulating layer configured to cover a peripheral edge portion of the first electrode and arranged between the substrate and the sealing layer in a portion between two adjacent light emitting elements among the plurality of light emitting elements, and

a light shielding member arranged between the two adjacent light emitting elements among the plurality of light emitting elements, extending through the insulating layer, and extending in the insulating layer and the sealing layer in a direction intersecting the main surface.

Item 2. The device according to item 1, wherein

the light shielding member includes a portion extending through the sealing layer, and

in a direction parallel to a virtual line connecting centers of the first electrodes of the two adjacent light emitting elements among the plurality of light emitting elements, a width of the portion at a position where a height of the portion is halved is not larger than 2 μm.

Item 3. The device according to item 1 or 2, wherein the light shielding member is arranged to surround each of the plurality of light emitting elements.

Item 4. The device according to any one of items 1 to 3, wherein the light shielding member is in contact with the second electrode.

Item 5. The device according to item 4, wherein power is supplied to the second electrode via the light shielding member.

Item 6. The device according to any one of items 1 to 3, wherein

a power supply plug configured to supply power to the second electrode is arranged between the two adjacent light emitting elements among the plurality of light emitting elements, and

the light shielding member is arranged to partially surround each of the plurality of light emitting elements.

Item 7. The device according to item 6, wherein the light shielding member is not in contact with the second electrode.

Item 8. The device according to any one of items 1 to 7, wherein the light shielding member has an inverted tapered shape in which a sectional area in a direction parallel to the main surface is larger as a distance from the substrate becomes longer.

Item 9. The device according to item 8, wherein a taper angle between a side wall of the light shielding member and a virtual plane parallel to the main surface is not smaller than 40°.

Item 10. The device according to any one of items 1 to 9, wherein an upper end portion of the light shielding member is arranged at a position farther from the main surface than the second electrode.

Item 11. The device according to any one of items 1 to 10, wherein the light shielding member extends through the sealing layer.

Item 12. The device according to any one of items 1 to 11, wherein

a color filter layer is further arranged at a position farther from the substrate than the sealing layer, and

the light shielding member is arranged to the color filter layer.

Item 13. The device according to item 12, wherein the light shielding member extends through the color filter layer.

Item 14. The device according to item 12 or 13, wherein

the light shielding member comprises a first portion arranged in the color filter layer and a second portion, in contact with the first portion, arranged on a side closer to the substrate than the first portion, and

a width of an upper end, in contact with the first portion, of the second portion in a direction parallel to a virtual line connecting centers of the first electrodes of the two adjacent light emitting elements among the plurality of light emitting elements is larger than a width of the first portion in the direction.

Item 15. The device according to any one of items 1 to 14, wherein an upper end portion of the light shielding member has an eaves shape.

Item 16. The device according to any one of items 1 to 15, further comprising a microlens at a position farther from the substrate than the sealing layer.

Item 17. The device according to item 16, wherein the light shielding member is in contact with the microlens.

Item 18. The device according to any one of items 1 to 17, wherein the light shielding member extends to separate from the substrate from a height at which the first electrode is arranged.

Item 19. A display device comprising the light emitting device according to any one of items 1 to 18, and an active element connected to the light emitting device.

Item 20. A photoelectric conversion device comprising an optical unit including a plurality of lenses, an image sensor configured to receive light having passed through the optical unit, and a display configured to display an image,

wherein the display displays an image captured by the image sensor, and comprises the light emitting device according to any one of items 1 to 18.

Item 21. An electronic apparatus comprising a housing provided with a display, and a communication unit provided in the housing and configured to perform external communication,

wherein the display comprises the light emitting device according to any one of items 1 to 18.

Item 22. An illumination device comprising a light source, and at least one of a light diffuser or an optical film, wherein the light source comprises a light emitting device according to any one of items 1 to 18.

Item 23. A moving body comprising a main body, and a lighting appliance provided in the main body,

wherein the lighting appliance comprises the light emitting device according to any one of items 1 to 18.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2021-164292, filed Oct. 5, 2021, Japanese Patent Application No. 2021-197871, filed Dec. 6, 2021, and Japanese Patent Application No. 2022-118156, filed Jul. 25, 2022, which are hereby incorporated by reference herein in their entirety.

What is claimed is:

1. A light emitting device in which a plurality of light emitting elements sealed by a sealing layer are arranged on a main surface of a substrate,
wherein each of the plurality of light emitting elements comprises a first electrode arranged between the substrate and the sealing layer, a second electrode arranged between the first electrode and the sealing layer, and an organic layer including a light emitting layer arranged between the first electrode and the second electrode, and
the light emitting device further comprises
an insulating layer configured to cover a peripheral edge portion of the first electrode and arranged between the substrate and the sealing layer in a portion between two adjacent light emitting elements among the plurality of light emitting elements, and
a light shielding member arranged between the two adjacent light emitting elements among the plurality of light emitting elements, extending through the insulating layer, and extending in the insulating layer and the sealing layer in a direction intersecting the main surface.

2. The device according to claim 1, wherein
the light shielding member includes a portion extending through the sealing layer, and
in a direction parallel to a virtual line connecting centers of the first electrodes of the two adjacent light emitting elements among the plurality of light emitting elements, a width of the portion at a position where a height of the portion is halved is not larger than 2 μm.

3. The device according to claim 1, wherein the light shielding member is arranged to surround each of the plurality of light emitting elements.

4. The device according to claim 1, wherein the light shielding member is in contact with the second electrode.

5. The device according to claim 4, wherein power is supplied to the second electrode via the light shielding member.

6. The device according to claim 1, wherein
a power supply plug configured to supply power to the second electrode is arranged between the two adjacent light emitting elements among the plurality of light emitting elements, and
the light shielding member is arranged to partially surround each of the plurality of light emitting elements.

7. The device according to claim 6, wherein the light shielding member is not in contact with the second electrode.

8. The device according to claim 1, wherein the light shielding member has an inverted tapered shape in which a sectional area in a direction parallel to the main surface is larger as a distance from the substrate becomes longer.

9. The device according to claim 8, wherein a taper angle between a side wall of the light shielding member and a virtual plane parallel to the main surface is not smaller than 40°.

10. The device according to claim 1, wherein an upper end portion of the light shielding member is arranged at a position farther from the main surface than the second electrode.

11. The device according to claim 1, wherein the light shielding member extends through the sealing layer.

12. The device according to claim 1, wherein
a color filter layer is further arranged at a position farther from the substrate than the sealing layer, and
the light shielding member is arranged to the color filter layer.

13. The device according to claim 12, wherein the light shielding member extends through the color filter layer.

14. The device according to claim 12, wherein
the light shielding member comprises a first portion arranged in the color filter layer and a second portion, in contact with the first portion, arranged on a side closer to the substrate than the first portion, and
a width of an upper end, in contact with the first portion, of the second portion in a direction parallel to a virtual line connecting centers of the first electrodes of the two adjacent light emitting elements among the plurality of light emitting elements is larger than a width of the first portion in the direction.

15. The device according to claim 1, wherein an upper end portion of the light shielding member has an eaves shape.

16. The device according to claim 1, further comprising a microlens at a position farther from the substrate than the sealing layer.

17. The device according to claim 16, wherein the light shielding member is in contact with the microlens.

18. The device according to claim 1, wherein the light shielding member extends to separate from the substrate from a height at which the first electrode is arranged.

19. A display device comprising the light emitting device according to claim 1, and an active element connected to the light emitting device.

20. A photoelectric conversion device comprising an optical unit including a plurality of lenses, an image sensor configured to receive light having passed through the optical unit, and a display configured to display an image,
wherein the display displays an image captured by the image sensor, and comprises the light emitting device according to claim 1.

21. An electronic apparatus comprising a housing provided with a display, and a communication unit provided in the housing and configured to perform external communication,
wherein the display comprises the light emitting device according to claim 1.

22. An illumination device comprising a light source, and at least one of a light diffuser or an optical film,
wherein the light source comprises a light emitting device according to claim 1.

23. A moving body comprising a main body, and a lighting appliance provided in the main body,
wherein the lighting appliance comprises the light emitting device according to claim 1.
